(19) United States
(12) Patent Application Publication
(10) Pub. No.: US 2024/0158692 A1
(43) Pub. Date: May 16, 2024

(54) IN-SITU CORE/SHELL NANOPARTICLE STRUCTURED METAL HALIDE PEROVSKITE LUMINESCENT MATERIAL, LIGHT EMITTING DEVICE INCLUDING THE SAME, AND MANUFACTURING METHOD THEREOF

(71) Applicants: SEOUL NATIONAL UNIVERSITY R&DB FOUNDATION, Seoul (KR); PEROLED Co., Ltd., Seoul (KR)

(72) Inventors: Tae-Woo LEE, Seoul (KR); Joo Sung KIM, Seoul (KR)

(21) Appl. No.: 18/485,135

(22) Filed: Oct. 11, 2023

(30) Foreign Application Priority Data
Oct. 31, 2022 (KR) 10-2022-0142652

(51) Int. Cl. C09K 11/02; H10K 50/115

(52) U.S. Cl. CPC C09K 11/025; H10K 50/115

(57) ABSTRACT

The present inventive concept relates to an in situ core/shell perovskite nanocrystal film formed by an in situ nanocrystal synthesis process, a method for producing the same, and a light emitting device comprising the same as a light-emitting layer. The in situ core/shell perovskite nanocrystal film formed by the in situ nanocrystal synthesis process according to the present inventive concept exhibits a strong charge confinement effect by nanocrystal formation, and can simultaneously greatly improve the luminescence efficiency and lifetime by maintaining the fast charge transport capability of polycrystalline perovskite.

### TECHNICAL FIELD

The present inventive concept relates to a metal halide perovskite luminescent material with an in situ core/shell nanoparticle structure, a light emitting device comprising the same, and a method of manufacturing the same.

### BACKGROUND ART

The current mega-trend in the display market is moving away from high-efficiency, high-resolution-oriented displays to emotional quality displays that aim to achieve natural colors through high color purity. In this regard, organic light-emitting diode (OLED) devices based on organic light emitters have made great strides, and inorganic quantum dot light-emitting diodes (QD LEDs) with excellent color purity are being actively researched and developed as an alternative. However, both organic and inorganic quantum dot light emitters have inherent material limitations.

Conventional organic light emitters have the advantage of high luminescence efficiency, but their color purity is poor due to their wide emission spectrum. On the other hand, inorganic quantum dot light emitters are known to have good color purity, but since light emission is affected by the quantum size effect, it becomes difficult to control the uniformity of the quantum dot size toward the high energy side (blue light), resulting in light emission from various sizes of quantum dots, which leads to poor color purity. In addition, both types of light emitters have the disadvantage of being expensive materials. Therefore, there is a need for a new luminescent material that complements the disadvantages of these organic and inorganic quantum dot light-emitters while retaining their advantages.

Metal halide perovskite materials have attracted significant academic and industrial attention due to their very low cost, simple fabrication and device fabrication processes, easy tunability of optical and electrical properties through simple chemical composition adjustments, and high charge mobility. In particular, metal halide perovskite materials have excellent properties as light emitters because they not only have high photoluminescence quantum efficiency, but also have high color purity and simple color control.

Materials with a conventional perovskite structure (ABX₃) are inorganic metal oxides. These inorganic metal oxides are typically oxides, with metal (alkali metals, alkaline earth metals, transition metals, and lanthanides) cations of different sizes, such as Ti, Sr, Ca, Cs, Ba, Y, Gd, La, Fe, and Mn, located at the A and B sites, An oxygen anion is located at the X site, and the metal cations at the B site are bonded to the oxygen anions at the X site in a corner-sharing octahedron with a 6-fold coordination. Examples include SrFeO₃, LaMnO₃, CaFeO₃, etc.

Metal halide perovskites, on the other hand, are completely different in composition from inorganic metal oxide perovskite materials, as the ABX₃ structure has organoammonium (RNH₃) cations, organophosphonium (RPH₃) cations, or alkali metal cations at the A sites, and halide anions (Cl⁻, Br⁻, I⁻) at the X sites to form the perovskite structure.

The differences in these constituent materials also determine the properties of the material. Perovskites, an inorganic metal oxide, typically exhibit superconductivity, ferroelectricity, and colossal magnetoresistance, and have been studied for applications in sensors, fuel cells, and memory devices. For example, yttrium barium copperoxide can be either superconducting or insulating depending on its oxygen content.

Metal halide perovskites, on the other hand, are often used as light emitters or photosensitizers due to their high light absorption coefficient, high photoluminescence quantum efficiency, and high color purity (<20 nm half -width), which is attributed to the crystal structure itself.

Even if, among metal halide perovskite materials, it is an organic-inorganic hybrid perovskite (i.e., organometallic halide perovskite), if the organoammonium contains a chromophore (mainly a conjugated structure) with a smaller bandgap than the crystal structure consisting of central metal and halogen (i.e. BX₆ octahedral lattice), it will not emit high color purity light because the luminescence occurs in the organoammonium, and the full-width at half-maximum of the luminescence spectrum will be wider than 100 nm, making it unsuitable as a light-emitting layer. Therefore, it is very unsuitable for the high color purity light emitters emphasized in the present patent. Therefore, in order to make a high color purity light emitter, it is important that the organoammonium does not contain a chromophore and that the light emission occurs in an inorganic lattice composed of a central metal-halogen element. In other words, the present patent focuses on the development of a high color purity and high efficiency light emitter in which light emission occurs in an inorganic lattice.

For example, Korean Public Patent No. 10-2001-0015084 (Feb. 26, 2001) discloses an electroluminescent device in which a dye-containing organic-inorganic hybrid material is formed into a thin film rather than particles and used as a light-emitting layer, but the light emission does not come from the perovskite lattice structure.

However, metal halide perovskites have small exciton binding energies, so while they can show luminescence at low temperatures, there is a fundamental problem at room temperature: thermal ionization and delocalization of the charge carriers prevent the excitons from giving radiative emission and cause them to separate into free charges and dissipate. In addition, when the free charge carriers recombines to form an exciton, the exciton is quenched by the surrounding highly conductive layer and no luminescence occurs.

There are fundamental structural differences between metal halide perovskite crystals that are typically used as the light-absorbing layer in solar cells and metal halide perovskite light emitters. Polycrystalline perovskite thin films with a large grain size (>100 nm) have been used for solar cells. In polycrystalline thin films with a grain size above a certain size (approximately 100 nm), metal halide perovskites have an inherently small exciton binding energy, so they can emit light at low temperatures, but at room temperature, due to thermal ionization and delocalization of charge carriers, the excitons do not proceed to emit light and are dissipated as free charges. In addition, when the free charges recombine to form excitons, the excitons are dissipated by the surrounding highly conductive layer, preventing light emission, making perovskite thin films suitable for use as light-absorbing layers in solar cells but not as light emitters. There have been some previous reports of stabilizing the surface to prevent the excitons from dissociating as free charges at the interface with the surrounding conductive layer and defects in the surface (Nature, 2018, 562, 245), but they have shown external quantum efficiencies as low as 20%, poor reproducibility, and short lifetimes.

To solve this problem, research is being conducted to synthesize metal halide perovskites as nanocrystal particles instead of thin films. The synthesis of metal halide nanocrystal particles is disclosed in Korean Patent No. 10-1815588 (Dec. 29, 2017), in which the inventors synthesize nanocrystal particles with improved efficiency, durability, and stability.

However, metal halide perovskite nanocrystals used as light emitters have a large surface-to-volume ratio due to their small particle size of a few nanometers to tens of nanometers, and can therefore have a high defect concentration. Therefore, it is essential to develop technologies that can simultaneously and effectively control the defects that can form on the surface of the nanocrystals as well as inside the perovskite crystals.

To solve this problem, many studies have been conducted to optimize ligands that bind to the surface of nanocrystals and inhibit defect formation, but most of them utilize hydrogen bonding of ammonium (—NH₃⁺) groups or electrostatic bonding of carboxylic acid (—COO⁻) groups, which causes the ligands to be easily detached during device operation and long-term operation.

In addition, metal halide perovskite nanocrystals used as light emitters are limited by the excessive use of insulating ligands with long alkyl groups during synthesis to provide solution-phase stability of the nanocrystals and prevent crystal agglomeration, which greatly reduces the charge transport capability of the nanocrystals. This greatly reduces the efficiency of charge injection and transport when applied to light-emitting devices, resulting in degradation due to charge accumulation, and low efficiency and lifetime. Therefore, it is essential to develop a technology that can realize a perovskite nanocrystal structure with a strong charge confinement effect while maintaining the high charge transport capability of perovskite materials.

In addition, to date, metal halide perovskites, unlike conventional organic or inorganic quantum dot light emitters, maintain their crystal structure through weak ionic bonding, which greatly reduces the stability of the material. For example, although the external quantum efficiency of FAₓGA₁₋ₓPbBr₃ based green light-emitting diodes is reported to be as high as 23.4% [Nature Photonics 2018, 15, 148-155] or higher, but the operational lifetime of the electrically driven light-emitting diodes is very low, around 2 h. Therefore, it is necessary to study the ways to improve the light-emission lifetime of metal halide perovskite luminescent materials.

In this regard, there is a need for a light emitter structure that can simultaneously have high efficiency and lifetime by achieving the strong charge confinement effect of the nanocrystal perovskite structure while maintaining the high charge transport capability of the polycrystalline perovskite structure. However, to date, research has mainly focused on synthesizing nanocrystal structures by using excessive amounts of insulating ligands and improving the charge transport capability by exchanging ligands after synthesizing nanocrystal structures, and no research has synthesized nanocrystal structures directly from polycrystalline perovskite structures.

### DISCLOSURE

### Technical Problem

Accordingly, the present inventive concept is conceived to address the above problems, and a first objective of the present inventive concept is to provide a core/shell nanocrystal perovskite luminescent material formed via an in situ process.

Furthermore, a second objective of the present inventive concept is to provide a method of producing a core/shell nanocrystal perovskite luminescent material formed via the above in situ process.

Furthermore, a third objective of the present inventive concept is to provide a light-emitting device comprising the above in situ core/shell nanocrystal perovskite film as a light-emitting layer.

### Technical Solution

To achieve the above first objective, the present inventive concept provides a core/shell halide perovskite nanocrystal having a core comprising halide perovskite nanocrystal of the structure ABX₃ (3D), A₄BX₆ (0D), AB₂X₅ (2D), A₂BX₄ (2D), A₂BX₆ (0D), A₂B⁺B³⁺X₆ (3D), A₃B₂X₉ (2D) or Aₙ₋₁BₙX₃ₙ₊₁ (quasi-2D), wherein n is an integer between 2 and 6 and a self-assembled shell surrounding the above core, wherein the above core/shell crystal structure comprises an organic acid compound (Y) of formula 1 below, providing a perovskite material, wherein the above perovskite nanocrystals have in situ core/shell nanocrystal structures in which a solid phase having an original polycrystalline morphology is progressively cleaved to form nanocrystals through an in situ chemical reaction with a solution of the organic ligand (Y), and the organic ligand (Y) binds to and surrounds the surface of the perovskite nanocrystals to form an core/shell structure.

The organic ligand (Y) binds to the surface of the perovskite and passivates the defect, and can be a phosphonic acid, a carboxylic acid, sulfonic acid, alkyl halide, alkyl ammonium halide, alkyl amine, or alkali halide. Of these, phosphonic acid may be the most potent, and the phosphonic acid that any aromatic group is attached to may be a candidate for an organic ligand (Y) material.

The phosphonic acids include phenylphosphonic acid, phenylmethylphosphonic acid, 2-phenylethylphosphonic acid, and vinylphosphonic acid, propadienylphosphonic acid, methylphosphonic acid, ethylphosphonic acid, propylphosphonic acid, and isopropylphosphonic acid, butylphosphonic acid, pentylphosphonic acid, n-hexylphosphonic acid, n-octylphosphonic acid, n-decylphosphonic acid, and n-dodecylphosphonic acid, n-tetradecylphosphonic acid, n-hexadecylphosphonic acid, and n-octadecylphosphonic acid, but is not limited thereto.

The alkyl halide may be of the structure alkyl-X. The halogen element corresponding to X may include Cl, Br, or I, for example. Also, the alkyl structure may include an acyclic alkyl having the structure of CₙH_{2n+1,}; a primary alcohol, a secondary alcohol, and a tertiary alcohol having the structure of CₙH₂ₙ₊₁OH; an alkylamine having the structure of alkyl-N (ex. Hexadecyl amine, 9-Octadecenylamine 1-Amino-9-octadecene (C₁₉H₃₇N)), p-substituted aniline, phenyl ammonium, or fluorine ammonium, but is not limited thereto.

The amine ligands may be selected from phenylamine, benzylamine, phenethylamine, (N,N-diisopropylethylethylamine), ethylenediamine, hexamethylenediamine, methylamine, and hexyl amine, oleylamine, N,N,N,N,N-tetramethylenediamine, triethylamine, diethanolamine, 2,2-(ethylenedioxyl)bis-(ethylamine), and 2,2-(ethylenedioxyl)bis-(ethylamine), but are not limited thereto.

Alkyl ammonium halide or alkylammonium salt includes methylammonium chloride, dimethylammonium bromide, and octylammonium bromide and in some cases halide in the structures may be replaced by fluoride or acetate as a salt form (e.g., ethyl dimethylammonium fluoride, tetrabenzylammonium acetate), but is not limited thereto.

The carboxylic acids include 4,4′-azobis(4-cyanovaleric acid), acetic acid, 5-aminosalicylic acid, acrylic acid, L-aspentic acid, 6-bromohexanoic acid, bromoacetic acid, dichloro acetic acid, ethylenediaminetetraacetic acid, isobutyric acid, itaconic acid, maleic acid, r-maleimidobutyric acid, L-malic acid, 4-nitrobenzoic acid, 1-pyrenecarboxylic acid, or oleic acid.

The organic ligand may be in a fluorinated form. For example, the organic ligand may be 2-fluorophenylbornic acid, 3,5-diformyl-2-fluorophenylboronic acid, 3-chloro-4-fluorophenylboronic acid, 4-cyano-3-fluprpbenzoic acid, L-Fmoc-3-fluorophenylalanine, L-Fmoc-4-fluorophenylalanine, and L-Fmoc-4-fluorophenylalanine, Methyl 6-fluorochromone-2-carboxylic acid, 4-fluorobenzoic acid, 2-fluorobenzoic acid, 2-fluoro benzylamine, 2-fluorocinnamic acid, 2-fluorophenyl isothiocyanate, and 4-fluorobenzenesulfonic acid, 4-flurobenzylamine, 4-fluorophenyl isothiocyanate, and 4-fluorophenylacetic acid, fluorocinnamic acid, (3-Fluoro-4-methylphenyl)acetic acid, (3-fluoro-5-isopropoxyphenyl)boronic acid, (3-fluoro-5-isopropoxyphenyl)boronic acid, (3-fluoro-5-methoxycarbonylphenyl)boronic acid ((3-fluoro-5-methoxycarbonylphenyl)boronic acid), (3-fluoro-5-methylphenyl)boronic acid ((3-fluoro-5-methylphenyl)boronic acid), (4-fluoro-2-methoxyphenyl)oxoacetic acid ((4-fluoro-2-methoxyphenyl)oxoacetic acid), (4-fluoro-3-methoxyphenyl)acetic acid, (4-fluoro-3-methoxyphenyl)boronic acid, and combinations thereof, including, but not limited to, (4-fluoro-3-methoxyphenyl)acetic acid and (4-fluoro-3-methoxyphenyl)boronic acid.

Furthermore, the preferably fluorinated organic compound may be in the form of a perfluorinated compound. The above perfluorinated compounds are perfluorinated alkyl halides, perfluorinated aryl halides, fluorochloroalkenes, perfluoroalcohols, perfluoamine, perfluorocarboxylic acid, perfluorosulfonic acid, or derivatives thereof.

The above perfluorinated alkyl halides and perfluorinated aryl halides include trifluoroiodomethane, pentafluoroethyl iodide, perfluorooctyl bromide (perflubron), dichlorodifluoromethane, and derivatives thereof.

The above fluorochloroalkene may be, but is not limited to, chlorotrifluoroethylene, dichlorodifluoroethylene, and derivatives thereof.

The above fluorochloroalkene may be, but is not limited to, chlorotrifluoroethylene, dichlorodifluoroethylene, and derivatives thereof.

The above perfluorocarboxylic acid may be, but is not limited to, trifluoroacetic acid, heptafluorobutryric acid, pentafluorobenzoic acid, and derivatives thereof, perfluorooctanoic acid, perfluorononanoic acid, and derivatives thereof.

The above perfluorosulfonic acid may be, but is not limited to, triflic acid, perfluorobuanesulfonic acid, perfluorobutane sulfonamide, perfluorooctanesulfonic acid, and derivatives thereof.

The ligands may be, but are not limited to, triocrylphosphine oxide (TOPO), trioctylphosphine (TOP), triethylphosphine oxide, tributylphosphine oxide, and derivatives thereof.

Further, to achieve the above second objective, the present inventive concept provides a method of preparing a perovskite film having an in situ core/shell nanocrystal structure comprising the steps of applying a ligand solution to a perovskite polycrystalline film to synthesize nanocrystals by splitting the polycrystals and thus forming the in situ core/shell nanocrystals surrounded by an organic acid compound in the ligand solution.

The solvent for the above ligand solution can be a polar solvent, for example, water, alcohol (methanol, ethanol, n-propanol, 2-propanol, n-butanol, methyl pyrrolidone (NMP), n-Methyl-2-Pyrrolidone, N-dimethylacetamide (N.N-dimethylacetamide), dimethylformamide (DMF), dimethyl sulfoxide (DMSO), tetrahydrofuran (THF), ethyl acetate (EtOAc), acetone, and acetonitrile (MeCN).

The ligand solution may be at a concentration of 1 mM to 100 mM. For example, 1 mM, 1.1 mM, 1.2 mM, 1.3 mM, 1.4 mM, 1.5 mM, 1.6 mM, 1.7 mM, 1.8 mM, 1.9 mM, 2 mM, 2.1 mM, 2.2 mM, 2.3 mM, 2.4 mM, 2.5 mM, 2.6 mM, 2.7 mM, 2.8 mM, 2.9 mM, 3 mM, 3.1 mM, 3.2 mM, 3.3 mM, 3.4 mM, 3.5 mM, 3.6 mM, 3.7 mM, 3.8 mM, 3.9 mM, 4 mM, 4.1 mM, 4.2 mM, 4.3 mM, 4.4 mM, 4.5 mM, 4.6 mM, 4.7 mM, 4.8 mM, 4.9 mM, 5 mM, 5.1 mM, 5.2 mM, 5.3 mM, 5.4 mM, 5.5 mM, 5.6 mM, 5.7 mM, 5.8 mM, 5.9 mM, 6 mM, 6.1 mM, 6.2 mM, 6.3 mM, 6.4 mM, 6.5 mM, 6.6 mM, 6.7 mM, 6.8 mM, 6.9 mM, 7 mM, 7.1 mM, 7.2 mM, 7.3 mM, 7.4 mM, 7.5 mM, 7.6 mM, 7.7 mM, 7.8 mM, 7.9 mM, 8 mM, 8.1 mM, 8.2 mM, 8.3 mM, 8.4 mM, 8.5 mM, 8.6 mM, 8.7 mM, 8.8 mM, 8.9 mM, 9 mM, 9.1 mM, 9.2 mM, 9.3 mM, 9.4 mM, 9.5 mM, 9.6 mM, 9.7 mM, 9.8 mM, 9.9 mM, 10 mM, 10.1 mM, 10.2 mM, 10.3 mM, 10.4 mM, 10.5 mM, 10.6 mM, 10.7 mM, 10.8 mM, 10.9 mM, 11 mM, 11.1 mM, 11.2 mM, 11.3 mM, 11.4 mM, 11.5 mM, 11.6 mM, 11.7 mM, 11.8 mM, 11.9 mM, 12 mM, 12.1 mM, 12.2 mM, 12.3 mM, 12.4 mM, 12.5 mM, 12.6 mM, 12.7 mM, 12.8 mM, 12.9 mM, 13 mM, 13.1 mM, 13.2 mM, 13.3 mM, 13.4 mM, 13.5 mM, 13.6 mM, 13.7 mM, 13.8 mM, 13.9 mM, 14 mM, 14.1 mM, 14.2 mM, 14.3 mM, 14.4 mM, 14.5 mM, 14.6 mM, 14.7 mM, 14.8 mM, 14.9 mM, 15 mM, 15.1 mM, 15.2 mM, 15.3 mM, 15.4 mM, 15.5 mM, 15.6 mM, 15.7 mM, 15.8 mM, 15.9 mM, 16 mM, 16.1 mM, 16.2 mM, 16.3 mM, 16.4 mM, 16.5 mM, 16.6 mM, 16.7 mM, 16.8 mM, 16.9 mM, 17 mM, 17.1 mM, 17.2 mM, 17.3 mM, 17.4 mM, 17.5 mM, 17.6 mM, 17.7 mM, 17.8 mM, 17.9 mM, 18 mM, 18.1 mM, 18.2 mM, 18.3 mM, 18.4 mM, 18.5 mM, 18.6 mM, 18.7 mM, 18.8 mM, 18.9 mM, 19 mM, 19.1 mM, 19.2 mM, 19.3 mM, 19.4 mM, 19.5 mM, 19.6 mM, 19.7 mM, 19.8 mM, 19.9 mM, 20 mM, 20.1 mM, 20.2 mM, 20.3 mM, 20.4 mM, 20.5 mM, 20.6 mM, 20.7 mM, 20.8 mM, 20.9 mM, 21 mM, 21.1 mM, 21.2 mM, 21.3 mM, 21.4 mM, 21.5 mM, 21.6 mM, 21.7 mM, 21.8 mM, 21.9 mM, 22.7 mM, 22.8 mM, 22.9 mM, 23 mM, 23.1 mM, 23.2 mM, 23.3 mM, 23.4 mM, 23.5 mM, 23.6 mM, 23.7 mM, 23.8 mM, 23.9 mM, 24 mM, 24.1 mM, 24.2 mM, 24.3 mM, 24.4 mM, 24.5 mM, 24.6 mM, 24.7 mM, 24.8 mM, 24.9 mM, 25 mM, 25.1 mM, 25.2 mM, 25.3 mM, 25.4 mM, 25.5 mM, 25.6 mM, 25.7 mM, 25.8 mM, 25.9 mM, 26 mM, 26.1 mM, 26.2 mM, 26.3 mM, 26.4 mM, 26.5 mM, 26.6 mM, 26.7 mM, 26.8 mM, 26.9 mM, 27 mM, 27.1 mM, 27.2 mM, 27.3 mM, 27.4 mM, 27.5 mM, 27.6 mM, 27.7 mM, 27.8 mM, 27.9 mM, 28 mM, 28.1 mM, 28.2 mM, 28.3 mM, 28.4 mM, 28.5 mM, 28.6 mM, 28.7 mM, 28.8 mM, 28.9 mM, 29 mM, 29.1 mM, 29.2 mM, 29.3 mM, 29.4 mM, 29.5 mM, 29.6 mM, 29.7 mM, 29.8 mM, 29.9 mM, 30 mM, 31 mM, 32 mM, 33 mM, 34 mM, 35 mM, 36 mM, 37 mM, 38 mM, 39 mM, 40 mM, 41 mM, 42 mM, 43 mM, 44 mM, 45 mM, 46 mM, 47 mM, 48 mM, 49 mM, 50 mM, 51 mM, 52 mM, 53 mM, 54 mM, 55 mM, 56 mM, 57 mM, 58 mM, 59 mM, 60 mM, 65 mM, 70 mM, 75 mM, 80 mM, 85 mM, 90 mM, 95 mM, 100 mM, 110 mM, 120 mM, 130 mM, 140 mM, 150 mM, 160 mM, 170 mM, 180 mM, 190 mM, 200 mM, 250 mM, 300 mM, 350 mM, 400 mM, 450 mM, 500 mM, 550 mM, 600 mM, 650 mM, 700 mM, 750 mM, 800 mM, 850 mM, 900 mM, 950 mM, 1000 mM. Preferably, it can be at least 1 mM and no more than 100 mM. More preferably, it may be more than 5 mM and less than 30 mM. More preferably, it may be more than 10 mM and less than 20 mM.

The time for reacting the above ligand solution to the perovskite polycrystalline film may be from 0 seconds to 100 seconds. For example, 0 s, 5 s, 10 s, 15 s, 20 s, 21 s, 22 s, 23 s, 24 s, 25 s, 26 s, 27 s, 28 s, 29 s, 30 s, 30.1 s, 30.2 s, 30.3 s, 30.4 s, 30.5 s, 30.6 s, 30.7 s, 30.8 s, 30.9 s, 31 s, 31.1 s, 31.2 s, 31.3 s, 31.4 s, 31.5 s, 31.6 s, 31.7 s, 31.8 s, 31.9 s, 32 s, 32.1 s, 32.2 s, 32.3 s, 32.4 s, 32.5 s, 32.6 s, 32.7 s, 32.8 s, 32.9 s, 33 s, 33.1 s, 33.2 s, 33.3 s, 33.4 s, 33.5 s, 33.6 s, 33.7 s, 33.8 s, 33.9 s, 34 s, 34.1 s, 34.2 s, 34.3 s, 34.4 s, 34.5 s, 34.6 s, 34.7 s, 34.8 s, 34.9 s, 35 s, 35.1 s, 35.2 s, 35.3 s, 35.4 s, 35.5 s, 35.6 s, 35.7 s, 35.8 s, 35.9 s, 36 s, 36.1 s, 36.2 s, 36.3 s, 36.4 s, 36.5 s, 36.6 s, 36.7 s, 36.8 s, 36.9 s, 37 s, 37.1 s, 37.2 s, 37.3 s, 37.4 s, 37.5 s, 37.6 s, 37.7 s, 37.8 s, 37.9 s, 38 s, 38.1 s, 38.2 s, 38.3 s, 38.4 s, 38.5 s, 38.6 s, 38.7 s, 38.8 s, 38.9 s, 39 s, 39.1 s, 39.2 s, 39.3 s, 39.4 s, 39.5 s, 39.6 s, 39.7 s, 39.8 s, 39.9 s, 40 s, 40.1 s, 40.2s, 40.3s, 40.4s, 40.5s, 40.6s, 40.7s, 40.8s, 40.9s, 41s, 41.1s, 41.2s, 41.3s, 41.4s, 41.5s, 41.6s, 41.7s, 41.8s, 41.9s, 42s, 42.1s, 42.2s, 42.3s, 42.4s, 42.5s, 42.6s, 42.7s, 42.8s, 42.9s, 43s, 43.1 second, 43.2 s, 43.3 s, 43.4 s, 43.5 s, 43.6 s, 43.7 s, 43.8 s, 43.9 s, 44 s, 44.1 s, 44.2 s, 44.3 s, 44.4 s, 44.5 s, 44.6 s, 44.7 s, 44.8 s, 44.9 s, 45 s, 45.1 s, 45.2 s, 45.3 s, 45.4 s, 45.5 s, 45.6 s, 45.7 s, 45.8 s, 45.9 s, 46 s, 46.1 s, 46.2 s, 46.3 s, 46.4 s, 46.5 s, 46.6 s, 46.7 s, 46.8 s, 46.9 s, 47 s, 47.1 s, 47.2 s, 47.3 s, 47.4 s, 47.5 s, 47.6 s, 47.7 s, 47.8 s, 47.9 s, 48 s, 48.1 s, 48.2 s, 48.3 s, 48.4 s, 48.5 s, 48.6 s, 48.7 s, 48.8 s, 48.9 s, 49 s, 49.1 s, 49.2 s, 49.3 s, 49.4 s, 49.5 s, 49.6 s, 49.7 s, 49.8 s, 49.9 s, 50 s, 51 s, 52 s, 53 s, 54 s, 55 s, 56 s, 57 s, 58 s, 59 s, 60 s, 65 s, 70 s, 75 s, 80 s, 85 s, 90 s, 95 s, 100 s. Preferably, it can be more than 10 s and less than 60 s. More preferably, it can be more than 20 s and less than 50 s. More preferably, it can be more than 30 s and less than 50 s.

Also preferably, the method of applying the above ligand solution may be selected from the group consisting of spin coating, bar coating, nozzle printing, spray coating, slot die coating, gravure printing, inkjet printing, screen printing, electrohydrodynamic jet printing, and electrospray.

In the above perovskite structure, the above A may be an organoammonium ion, an organophosphonium ion, or an alkali metal ion, the above B may be a transition metal, an alkaline earth metal, a rare earth metal, Pb, Sn, Ge, Ga, In, Al, Sb, Bi, Po, or a combination thereof, and the above X may be Cl, Br, I, a cyanide ion, a cyanide sulfide ion, or a combination thereof.

Also preferably, the above perovskite nanocrystals can have a crystal size equal to or greater than the exciton Bohr diameter (about 10 nm for MAPbBr₃, about 7 nm for CsPbBr₃, about 8 nm for FAPbBr₃) and less than or equal to 30 nm. For example, 7 nm, 7.5 nm, 8 nm, 8.3 nm, 8.5 nm, 8.7 nm, 9 nm, 9.3 nm, 9.5 nm, 9.7 nm, 10 nm, 10.3 nm, 10.5 nm, 10.7 nm, 11 nm, 11.3 nm, 11.5 nm, 11.7 nm, 12 nm, 12.3 nm, 12.5 nm, 12.7 nm, 13 nm, 13.3 nm, 13.5 nm, 13.7 nm, 14 nm, 14.3 nm, 14.5 nm, 14.7 nm, 15 nm, 15.3 nm, 15.5 nm, 15. 7 nm, 16 nm, 16.5 nm 17 nm, 17.5 nm, 18 nm, 18.5 nm, 19 nm, 19.5 nm, 20 nm, 21 nm, 22 nm, 23 nm, 24 nm, 25 nm, 26 nm, 27 nm, 28 nm, 29 nm, 30 nm.

Preferably, it may be at least 7 nm and no more than 25 nm. More preferably, it may be more than 10 nm and less than 20 nm. More preferably, it may be more than 10 nm and less than or equal to 15 nm.

Also preferably, the above perovskite light-emitting material can emit light in the region of 300 nm to 1500 nm. More preferably, it can emit light in the region of 430 nm to 780 nm. More preferably, it can emit light in the region of 450 nm to 650 nm. For example, 400 nm, 410 nm, 420 nm, 430 nm, 440 nm, 450 nm, 455 nm, 460 nm, 465 nm, 470 nm, 475 nm, 480 nm, 485 nm, 490 nm, 500 nm, 510 nm, 520 nm, 525 nm, 530 nm, 535 nm, 540 nm, 545 nm, 550 nm, 560 nm, 570 nm, 580 nm, 590 nm, 600 nm, 610 nm, 620 nm, 625 nm, 630 nm, 635 nm, 640 nm, 650 nm.

Further, to achieve the above third objective, the present inventive concept provides a perovskite light emitting device comprising a substrate, a first electrode located on the above substrate, a light-emitting layer located on the above first electrode, and a second electrode located on the above light-emitting layer, wherein the above light-emitting layer is a perovskite film having the above in situ core/shell nanocrystal structure.

Also preferably, the thickness of the above light-emitting layer may be from 10 nm to 10 μm.

Also preferably, the above first electrode or second electrode may comprise at least one selected from the group consisting of a metal, a conductive polymer, a metallic carbon nanotube, graphene, reduced graphene oxide, a metal nanowire, a carbon nanodot, a metal nanodot, and a conductive oxide, or a combination thereof.

Also preferably, the above light-emitting device may be selected from the group consisting of a light-emitting diode, a light-emitting transistor, a laser, and a polarized light-emitting device.

Further, to achieve the above third objective, the present inventive concept provides a perovskite light emitting device comprising a substrate; a first electrode located on the above substrate; a light-emitting layer located on the above first electrode; and a second electrode located on the above light-emitting layer, wherein the above light-emitting layer is the above perovskite light-emitting material.

### Advantageous Effect of the Inventive Concept

According to the present inventive concept, the in situ core/shell nanocrystal perovskite formed according to the in situ nanocrystal synthesis process can exhibit high luminescence efficiency through a strong charge confinement effect through crystal size reduction, and in the process of splitting the polycrystalline perovskite, the defects existing inside the crystal are revealed to the nanocrystal surface, and by being surrounded by ligands, both the defects inside the crystal and the defects on the surface are stabilized, thereby improving the photoluminescence quantum efficiency, luminescence lifetime and stability, which is useful for the light-emitting layer of the light emitting device.

In addition, according to the present inventive concept, a core/shell structure can be formed in which ligands surrounds the surface of the nanocrystal regardless of their length, so that, unlike conventional perovskite nanocrystals surrounded by insulating ligands, the high charge transport capability of perovskites can be maintained, which can be used to realize an ideal light-emitting device based on excellent electrical properties, high luminescence efficiency, and stability.

### DESCRIPTION OF DRAWINGS

FIG. 1 is a schematic of the synthesis of the in situ core/shell perovskite nanocrystal of the present inventive concept.

FIG. 2 is a schematic of the crystal size evolution during the synthesis of the in situ core/shell perovskite nanocrystal of the present inventive concept.

FIG. 3 is a scanning electron microscopy image showing the morphology of the perovskite film as a function of reaction time with the ligand solution when 0.6 M of perovskite precursor was utilized in the synthesis of the in situ core/shell perovskite nanocrystal of the present inventive concept.

FIG. 4 is a scanning electron microscopy and crystal size distribution graph of an in situ core/shell perovskite nanocrystal film synthesized during the synthesis of the in situ core/shell perovskite nanocrystal of the present inventive concept, starting from polycrystalline 3D, with the ligand self-assembled on the surface only, and with the crystal size fragmented to form nanocrystals.

FIG. 5 is a high magnification transmission electron microscopy (TEM) image (a-d) and magnified HAADF-STEM image (e-h) of the in situ core/shell perovskite nanocrystal of the present inventive concept as a function of reaction time with the ligand solution.

FIG. 6 shows a, scanning electron microscopy image, b, HAADF-STEM image, and c, high magnification TEM image of a perovskite nanocrystal that broke off from a larger perovskite crystal at the beginning of the reaction with the ligand solution (0 s) when 0.6 M of perovskite precursor was utilized in the synthesis of the in situ core/shell perovskite nanocrystal of the present inventive concept.

FIG. 7 is a HAADF-STEM image and enlargement of a perovskite nanocrystal showing a gradual decrease in size as the reaction with the ligand solution progresses, with the nanocrystal falling apart, when 0.6 M of perovskite precursor was utilized in the synthesis of the in situ core/shell perovskite nanocrystal of the present inventive concept.

FIG. 8 is a HAADF-STEM image and EEL spectrum at the boundary region between the core and shell of the in situ core/shell perovskite nanocrystal of the present inventive concept.

FIG. 9 is a HAADF-STEM image and EEL spectrum at the boundary region between the core and shell of the in situ core/shell perovskite nanocrystal of the present inventive concept.

FIG. 10 is a high magnification transmission electron microscopy and EDS scan image of an in situ core/shell perovskite nanocrystal film of the present inventive concept.

FIG. 11 is a high magnification transmission electron microscopy EDS spectrum of an in situ core/shell perovskite nanocrystal particle of the present inventive concept.

FIG. 12 is a schematic diagram illustrating a method for preparing an in situ core/shell perovskite nanocrystal film according to an embodiment of the present inventive concept.

FIG. 13 is an XPS spectrum graph of the oxygen element (O 1 s) of the in situ core/shell perovskite nanocrystal film of the present inventive concept.

FIG. 14 is a graph of the charge injection characteristics of a hole-only device following the formation of an in situ core/shell perovskite nanocrystal film of the present inventive concept.

FIG. 15 is a graph of steady-state photoluminescence intensity and photoluminescence lifetime following the formation of the in situ core/shell perovskite nanocrystal film of the present inventive concept.

FIG. 16 is a photoluminescence quantum yield measurement spectrum and an internal photoluminescence quantum yield versus external photoluminescence quantum yield graph for the formation of the in situ core/shell perovskite nanocrystal film of the present inventive concept.

FIG. 17 is a graph of photoluminescence spectra and photoluminescence intensity as a function of temperature for the formation of the in situ core/shell perovskite nanocrystal film of the present inventive concept.

FIG. 18 is a graph of luminance as a function of voltage, external quantum efficiency as a function of luminance for a perovskite light emitting diode based on the in situ core/shell nanocrystal structure formation of the present inventive concept.

FIG. 19 is a graph of power efficiency and current efficiency as a function of luminance for a perovskite light emitting diode based on the in situ core/shell nanocrystal structure formation of the present inventive concept.

FIG. 20 is a current versus voltage, current versus luminance graph of a perovskite light emitting diode according to the formation of the in situ core/shell nanocrystal structure of the present inventive concept.

FIG. 21 is an electroluminescence spectrum and color coordinate graph of a perovskite light emitting diode according to the formation of the in situ core/shell nanocrystal structure of the present inventive concept.

FIG. 22 is a histogram of external quantum efficiency as a function of applied temperature and nanocrystal pinning timing in a perovskite light emitting diode according to the in situ core/shell nanocrystal structure formation of the present inventive concept.

FIG. 23 is an external quantum efficiency histogram of a perovskite light emitting diode based on the formation of the in situ core/shell nanocrystal structure of the present inventive concept.

FIG. 24 is a graph of electroluminescence intensity as a function of angle for a perovskite light emitting diode based on the formation of the in situ core/shell nanocrystal structure of the present inventive concept.

FIG. 25 is a graph of the operational lifetime of a perovskite light emitting diode at an initial luminance of 10,000 cd m⁻² according to the in situ core/shell nanocrystal structure formation of the present inventive concept.

FIG. 26 is a graph of the operational lifetime of a perovskite light-emitting diode as a function of different initial luminance according to the formation of the in situ core/shell nanocrystal structure of the present inventive concept.

FIG. 27 is a photograph of the luminance depending on voltage, external quantum efficiency depending on current, and actual operation of a 100 mm² wide large-area light-emitting device fabricated based on the in situ core/shell perovskite nanocrystal light-emitting diode of the present inventive concept.

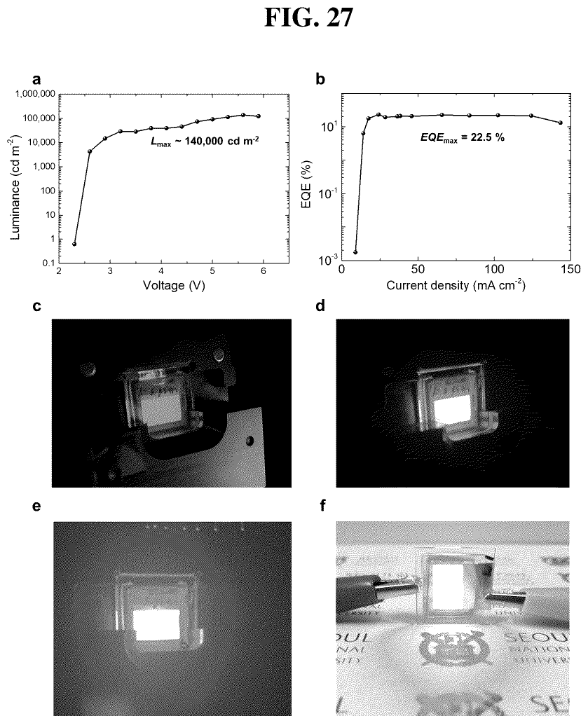

FIG. 28 is a schematic illustration of a light emitting device according to an embodiment of the present inventive concept.

FIG. 29 is a schematic illustration of a light emitting device according to an embodiment of the present inventive concept.

### MODES OF THE DISCLOSURE

Hereinafter, preferred embodiments of the present inventive concept will be described in more detail with reference to the accompanying drawings to further illustrate the inventive concept. However, the inventive concept is not limited to the embodiments described herein and may be embodied in other forms.

As used herein, terms such as first, second, and the like are used to describe various components, which components are not limited by such terms, but are used to distinguish one component from another. It is also to be understood that the present inventive concept is not limited to the particles or compositions described herein, but that all modifications or equivalents of the ideas of the present inventive concept are also included within the technical scope of the present inventive concept.

In this specification, the components of the accompanying drawings may be shown to scale for purposes of illustration.

Symbols in this specification are specific to the respective drawings in which they are included, and symbols in different drawings may represent different components, even though their notations are identical.

In order to achieve the above first objective, the present inventive concept provides a core comprising perovskite nanocrystals having the structure ABX₃ (3D), A₄BX₆ (0D), AB₂X₅ (2D), A₂BX₄ (2D), A₂BX₆ (0D), A₂B⁺B³⁺X₆(3D), A₃B₂X₉ (2D) or Aₙ₋₁BₙX₃ₙ₊₁ (quasi-2D), wherein n is an integer between 2 and 6, and a self-assembled shell surrounding the above core having a core/shell crystal structure comprising an organic acid compound (Y) of formula 1 below, providing a perovskite material characterized in that the above perovskite nanocrystals are an in situ core/shell nanocrystal structure in which a solid phase having an originally polycrystalline form is progressively cleaved to form nanocrystals by in situ chemical reaction with a solution of the organic ligand (Y), and the organic ligand (Y) binds to the surface of the perovskite nanocrystals to form an core/shell structure.

In the above perovskite structure, the above A may be an organoammonium ion, an organophosphonium ion, or an alkali metal ion, the above B may be a transition metal, an alkaline earth metal, a rare earth metal,

Pb, Sn, Ge, Ga, In, Al, Sb, Bi, Po, or a combination thereof, and the above X may be Cl, Br, I, a cyanide ion, a cyanide sulfide ion, or a combination thereof.

Also preferably, A is an organoammonium (RNH₃)⁺, , an organoamidinium derivative (RC(═NR₂)NR₂)⁺, an organoguanidinium derivative (R₂NC(═NR₂)NR₂)⁺, an organodiammonium (CₓH₂ₓ₋ₙ₊₄)(NH₃)n⁺, ((CₓH2ₓ₊₁)ₙNH₃)(CH₃NH₃)ₙ⁺, (RNH₃)₂⁺, (CₙH₂ₙ₊₁NH₃)₂⁺, (CF₃NH₃)⁺, (CF₃NH₃)ₙ⁺, ((CₓF₂ₓ₊₁)ₙNH₃)₂(CF₃NH₃)ₙ⁺, ((CₓF₂ₓ₊₁)ₙNH₃)₂⁺ or (CₙF₂ₙ₊₁NH₃)₂⁺ (x, n is an integer equal to or greater than 1, R=hydrocarbon derivative, H, F, Cl, Br, I) and combinations thereof. The alkali metal may be, but is not limited to, Li⁺, Na⁺, K⁺, Rb⁺, Cs⁺, Fr⁺ and combinations thereof. Also preferably, the above organic cation is selected from the group consisting of acetamidinium, azaspironanium, benzene diammonium, benzylammonium, butanediammonium, iso-butylammonium, n-butylammonium, t-butylammonium, cyclohexylammonium, cyclohexylmethylammonium, diazobicyclooctanedinium, diethylammonium, N,N-diehtylethane diammonium, N,N-diethylpropane diammonium, dimethylammonium, N,N-dimethylethane diammonium, dimethylpropane diammonium, N,N-dimethylpropane diammonium, dodecylammonium, ethanediammonium, ethylammoniuium, 4-fluoro-benzylammonium, 4-fluoro-phenylethylammonium, 4-fluoro-phenylammonium, and 4-fluoro-phenylammonium, formamidinium, guanidinium, hexanediammnium, hexylammonium, imidazolium, 2-methoxyethylammonium, and 4-methoxy-phenlylethylammonium, 4-methoxy-phenylammonium, methylammonium, morpholinium, octylammonium, pentylammonium, piperazinediium, and piperidinium, propanediammonium, iso-propylammonium, di-iso-propylammonium, n-propylammonium, pyridinium, 2-pyrrolidin-1-ium-1-yethylammonium, pyrrolidinium, quinclidin-1-ium, 4-trifluoromethyl-benzylammonium, 4-trifluoromethyl ammonium, and combinations thereof.

Furthermore, the above B may be a divalent transition metal, a rare 15 earth metal, an alkaline earth metal, a monovalent metal, a trivalent metal, and combinations thereof. Also preferably, the above bivalent transition metal, rare earth metal, alkaline earth metal may be, but is not limited to, Be²⁺, Mg²⁺, Ca²⁺, Sr²⁺, Ba²⁺, Ra²⁺, Mn²⁺, Fe²⁺, Co²⁺, Ni²⁺, Cu²⁺, Zn²⁺, Ru²⁺, Pd²⁺, Cd²⁺, Pt²⁺, Hg²⁺, Ge²⁺, Sn²⁺, Pb²⁺, Se²⁺, Te²⁺, Po²⁺ and combinations thereof. The monovalent metal may be Li⁺, Na⁺, K⁺, Rb⁺, Cs⁺, Fr⁺, Ag⁺, Hg⁺, Ti⁺ and combinations thereof, and the trivalent metal may be Cr³⁺, Fe³⁺, Co³⁺, Ru³⁺, Rh³⁺, Ir³⁺, Au³⁺, Al³⁺, Ga³⁺, In³⁺, Ti³⁺, As³⁺, Sb³⁺, Bi³⁺ and combinations thereof.

Preferably, the above organic ligand (Y) is a substance that binds to the surface of the perovskite and passivates the defects, such as phosphonic acid, carboxylic acid, sulfonic acid, alkyl halide, alkyl ammonium halide, alkyl amine, or alkali halide.

A ligand is a generic term for an ion or molecule that can be bound to a central atom in a coordination complex. The ligands bind to the surface of the nanoparticles and provide precise control over the shape and size of the nanoparticles. A detailed description of ligands can be found in [Journal of the American Chemistry Society, 2013, 135, 49, pp 18536-18548]. Ligands that bind to the surface of nanoparticles can be L-type ligands, X-type ligands, or Z-type ligands, depending on the mode of binding to the surface of the nanoparticle. L-type ligands are those that donate two electrons to form a dative bond, X-type ligands are those that donate one electron to a cationic site on the surface of the nanoparticle to form a covalent bond, and Z-type ligands are those that accept two electrons on the surface of the nanoparticle.

The phosphonic acids include phosphonic acid, phenylmethylphosphonic acid, 2-phenylethylphosphonic acid, and vinylphosphonic acid, propadienylphosphonic acid, methylphosphonic acid, ethylphosphonic acid, propylphosphonic acid, and isopropylphosphonic acid, butylphosphonic acid, pentylphosphonic acid, n-hexylphosphonic acid, n-octylphosphonic acid, n-decylphosphonic acid, and n-dodecylphosphonic acid, n-tetradecylphosphonic acid, n-hexadecylphosphonic acid, and n-octadecylphosphonic acid, but is not limited thereto.

The alkyl halide may be of the structure alkyl-X. The halogen element corresponding to X may include Cl, Br, or I, for example. Also, the alkyl structure may include an acyclic alkyl having the structure of CₙH₂ₙ₊₁ , a primary alcohol having the structure of CₙH₂ₙ₊₁OH, a secondary alcohol, a tertiary alcohol, an alkylamine having the structure of alkyl-N (ex. Hexadecyl amine, 9-Octadecenylamine 1-Amino-9-octadecene (C₁₉H₃₇N)), p-substituted aniline, phenyl ammonium, or fluorine ammonium, but is not limited thereto.

The amine ligands may be selected from phenylamine, benzylamine, phenethylamine, (N,N-diisopropylethylethylamine), ethylenediamine, hexamethylenediamine, methylamine, and hexyl amine, oleylamine, N,N,N,N,N-tetramethylenediamine, triethylamine, diethanolamine, 2,2-(ethylenedioxyl)bis-(ethylamine), and 2,2-(ethylenedioxyl)bis-(ethylamine), but are not limited thereto.

The term, alkyl ammonium halide or alkylammonium salt includes methylammonium chloride, dimethylammonium bromide, and octylammonium bromide) and in some cases may be replaced by fluoride or acetate as a salt form other than halide (e.g., ethyl dimethylammonium fluoride, tetrabenzylammonium acetate), but are not limited thereto.

The carboxylic acids include 4,4t-Azobis(4-cyanovaleric acid), acetic acid, 5-aminosalicylic acid, acrylic acid, L-aspentic acid, 6-bromohexanoic acid, bromoacetic acid, dichloro acetic acid, ethylenediaminetetraacetic acid, isobutyric acid, itaconic acid, maleic acid, r-maleimidobutyric acid, L-malic acid, 4-nitrobenzoic acid, 1-pyrenecarboxylic acid, or oleic acid.

The organic ligand may be in a fluorinated form. For example, the organic ligand may be 2-fluorophenylbornic acid, 3,5-diformyl-2-fluorophenylboronic acid, 3-chloro-4-fluorophenylboronic acid, 4-cyano-3-fluprpbenzoic acid, L-Fmoc-3-fluorophenylalanine, L-Fmoc-4-fluorophenylalanine, and L-Fmoc-4-fluorophenylalanine, Methyl 6-fluorochromone-2-carboxylic acid, 4-fluorobenzoic acid, 2-fluorobenzoic acid, 2-fluoro benzylamine, 2-fluorocinnamic acid, 2-fluorophenyl isothiocyanate, and 4-fluorobenzenesulfonic acid, 4-flurobenzylamine, 4-fluorophenyl isothiocyanate, and 4-fluorophenylacetic acid, Fluorocinnamic acid, (3-Fluoro-4-methylphenyl)acetic acid, (3-Fluoro-5-isopropoxyphenyl)boronic acid, (3-fluoro-5-isopropoxyphenyl)boronic acid, (3-fluoro-5-methoxycarbonylphenyl)boronic acid ((3-fluoro-5-methoxycarbonylphenyl)boronic acid), (3-fluoro-5-methylphenyl)boronic acid ((3-fluoro-5-methylphenyl)boronic acid), (4-fluoro-2-methoxyphenyl)oxoacetic acid ((4-fluoro-2-methoxyphenyl)oxoacetic acid), (4-fluoro-3-methoxyphenyl)acetic acid, (4-fluoro-3-methoxyphenyl)boronic acid, and combinations thereof, including, but not limited to, (4-fluoro-3-methoxyphenyl)acetic acid and (4-fluoro-3-methoxyphenyl)boronic acid.

Furthermore, the preferably fluorinated organic compound may be in the form of a perfluorinated compound. The above perfluorinated compounds are perfluorinated alkyl halides, perfluorinated aryl halides, fluorochloroalkenes, perfluoroalcohols, perfluoamine, perfluorocarboxylic acid, perfluorosulfonic acid, or derivatives thereof.

The above perfluorinated alkyl halides and perfluorinated aryl halides include trifluoroiodomethane, pentafluoroethyl iodide, perfluorooctyl bromide (perflubron), dichlorodifluoromethane, and derivatives thereof.

The above fluorochloroalkene may be, but is not limited to, chlorotrifluoroethylene, dichlorodifluoroethylene, and derivatives thereof.

The above fluorochloroalkene may be, but is not limited to, chlorotrifluoroethylene, dichlorodifluoroethylene, and derivatives thereof.

The above perfluorocarboxylic acid may be, but is not limited to, trifluoroacetic acid, heptafluorobutryric acid, pentafluorobenzoic acid, and derivatives thereof, perfluorooctanoic acid, perfluorononanoic acid, and derivatives thereof.

The above perfluorosulfonic acid may be, but is not limited to, triflic acid, perfluorobuanesulfonic acid, perfluorobutane sulfonamide, perfluorooctanesulfonic acid, and derivatives thereof.

The above ligands may be, but are not limited to, triocrylphosphine oxide (TOPO), trioctylphosphine (TOP), triethylphosphine oxide, tributylphosphine oxide, and derivatives thereof.

Further, to achieve the above second objective, the present inventive concept provides a method of preparing a perovskite film having an in situ core/shell nanocrystal structure, comprising the steps of applying a ligand solution to a perovskite polycrystalline film to synthesize crystal-splitting nanocrystals and an organic acid compound to form in situ core/shell nanocrystals surrounding the surface.

The solvent for the above ligand solution can be a polar solvent, for example, water, alcohol (methanol, ethanol, n-propanol, 2-propanol, n-butanol, methyl pyrrolidone (NMP), n-methyl-2-pyrrolidone, N-dimethylacetamide (N.N-dimethylacetamide), dimethylformamide (DMF), dimethyl sulfoxide (DMSO), tetrahydrofuran (THF), ethyl acetate (EtOAc), acetone, and acetonitrile (MeCN).

The ligand solution may be at a concentration of 1 mM to 100 mM. For example, 1 mM, 1.1 mM, 1.2 mM, 1.3 mM, 1.4 mM, 1.5 mM, 1.6 mM, 1.7 mM, 1.8 mM, 1.9 mM, 2 mM, 2.1 mM, 2.2 mM, 2.3 mM, 2.4 mM, 2.5 mM, 2.6 mM, 2.7 mM, 2.8 mM, 2.9 mM, 3 mM, 3.1 mM, 3.2 mM, 3.3 mM, 3.4 mM, 3.5 mM, 3.6 mM, 3.7 mM, 3.8 mM, 3.9 mM, 4 mM, 4.1 mM, 4.2 mM, 4.3 mM, 4.4 mM, 4.5 mM, 4.6 mM, 4.7 mM, 4.8 mM, 4.9 mM, 5 mM, 5.1 mM, 5.2 mM, 5.3 mM, 5.4 mM, 5.5 mM, 5.6 mM, 5.7 mM, 5.8 mM, 5.9 mM, 6 mM, 6.1 mM, 6.2 mM, 6.3 mM, 6.4 mM, 6.5 mM, 6.6 mM, 6.7 mM, 6.8 mM, 6.9 mM, 7 mM, 7.1 mM, 7.2 mM, 7.3 mM, 7.4 mM, 7.5 mM, 7.6 mM, 7.7 mM, 7.8 mM, 7.9 mM, 8 mM, 8.1 mM, 8.2 mM, 8.3 mM, 8.4 mM, 8.5 mM, 8.6 mM, 8.7 mM, 8.8 mM, 8.9 mM, 9 mM, 9.1 mM, 9.2 mM, 9.3 mM, 9.4 mM, 9.5 mM, 9.6 mM, 9.7 mM, 9.8 mM, 9.9 mM, 10 mM, 10.1 mM, 10.2 mM, 10.3 mM, 10.4 mM, 10.5 mM, 10.6 mM, 10.7 mM, 10.8 mM, 10.9 mM, 11 mM, 11.1 mM, 11.2 mM, 11.3 mM, 11.4 mM, 11.5 mM, 11.6 mM, 11.7 mM, 11.8 mM, 11.9 mM, 12 mM, 12.1 mM, 12.2 mM, 12.3 mM, 12.4 mM, 12.5 mM, 12.6 mM, 12.7 mM, 12.8 mM, 12.9 mM, 13 mM, 13.1 mM, 13.2 mM, 13.3 mM, 13.4 mM, 13.5 mM, 13.6 mM, 13.7 mM, 13.8 mM, 13.9 mM, 14 mM, 14.1 mM, 14.2 mM, 14.3 mM, 14.4 mM, 14.5 mM, 14.6 mM, 14.7 mM, 14.8 mM, 14.9 mM, 15 mM, 15.1 mM, 15.2 mM, 15.3 mM, 15.4 mM, 15.5 mM, 15.6 mM, 15.7 mM, 15.8 mM, 15.9 mM, 16 mM, 16.1 mM, 16.2 mM, 16.3 mM, 16.4 mM, 16.5 mM, 16.6 mM, 16.7 mM, 16.8 mM, 16.9 mM, 17 mM, 17.1 mM, 17.2 mM, 17.3 mM, 17.4 mM, 17.5 mM, 17.6 mM, 17.7 mM, 17.8 mM, 17.9 mM, 18 mM, 18.1 mM, 18.2 mM, 18.3 mM, 18.4 mM, 18.5 mM, 18.6 mM, 18.7 mM, 18.8 mM, 18.9 mM, 19 mM, 19.1 mM, 19.2 mM, 19.3 mM, 19.4 mM, 19.5 mM, 19.6 mM, 19.7 mM, 19.8 mM, 19.9 mM, 20 mM, 20.1 mM, 20.2 mM, 20.3 mM, 20.4 mM, 20.5 mM, 20.6 mM, 20.7 mM, 20.8 mM, 20.9 mM, 21 mM, 21.1 mM, 21.2 mM, 21.3 mM, 21.4 mM, 21.5 mM, 21.6 mM, 21.7 mM, 21.8 mM, 21.9 mM, 22.7 mM, 22.8 mM, 22.9 mM, 23 mM, 23.1 mM, 23.2 mM, 23.3 mM, 23.4 mM, 23.5 mM, 23.6 mM, 23.7 mM, 23.8 mM, 23.9 mM, 24 mM, 24.1 mM, 24.2 mM, 24.3 mM, 24.4 mM, 24.5 mM, 24.6 mM, 24.7 mM, 24.8 mM, 24.9 mM, 25 mM, 25.1 mM, 25.2 mM, 25.3 mM, 25.4 mM, 25.5 mM, 25.6 mM, 25.7 mM, 25.8 mM, 25.9 mM, 26 mM, 26.1 mM, 26.2 mM, 26.3 mM, 26.4 mM, 26.5 mM, 26.6 mM, 26.7 mM, 26.8 mM, 26.9 mM, 27 mM, 27.1 mM, 27.2 mM, 27.3 mM, 27.4 mM, 27.5 mM, 27.6 mM, 27.7 mM, 27.8 mM, 27.9 mM, 28 mM, 28.1 mM, 28.2 mM, 28.3 mM, 28.4 mM, 28.5 mM, 28.6 mM, 28.7 mM, 28.8 mM, 28.9 mM, 29 mM, 29.1 mM, 29.2 mM, 29.3 mM, 29.4 mM, 29.5 mM, 29.6 mM, 29.7 mM, 29.8 mM, 29.9 mM, 30 mM, 31 mM, 32 mM, 33 mM, 34 mM, 35 mM, 36 mM, 37 mM, 38 mM, 39 mM, 40 mM, 41 mM, 42 mM, 43 mM, 44 mM, 45 mM, 46 mM, 47 mM, 48 mM, 49 mM, 50 mM, 51 mM, 52 mM, 53 mM, 54 mM, 55 mM, 56 mM, 57 mM, 58 mM, 59 mM, 60 mM, 65 mM, 70 mM, 75 mM, 80 mM, 85 mM, 90 mM, 95 mM, 100 mM, 110 mM, 120 mM, 130 mM, 140 mM, 150 mM, 160 mM, 170 mM, 180 mM, 190 mM, 200 mM, 250 mM, 300 mM, 350 mM, 400 mM, 450 mM, 500 mM, 550 mM, 600 mM, 650 mM, 700 mM, 750 mM, 800 mM, 850 mM, 900 mM, 950 mM, 1000 mM. Preferably, it can be at least 1 mM and no more than 100 mM. More preferably, it may be more than 5 mM and less than 30 mM. More preferably, it may be more than 10 mM and less than 20 mM.

The time for reacting the above ligand solution to the perovskite polycrystalline film may be from 0 s to 100 s. For example, 0 s, 5 s, 10 s, 15 s, 20 s, 21 s, 22 s, 23 s, 24 s, 25 s, 26 s, 27 s, 28 s, 29 s, 30 s, 30.1 s, 30.2 s, 30.3 s, 30.4 s, 30.5 s, 30.6 s, 30.7 s, 30.8 s, 30.9 s, 31 s, 31.1 s, 31.2 s, 31.3 s, 31.4 s, 31.5 s, 31.6 s, 31.7 s, 31.8 s, 31.9 s, 32 s, 32.1 s, 32.2 s, 32.3 s, 32.4 s, 32.5 s, 32.6 s, 32.7 s, 32.8 s, 32.9 s, 33 s, 33.1 s, 33.2 s, 33.3 s, 33.4 s, 33.5 s, 33.6 s, 33.7 s, 33.8 s, 33.9 s, 34 s, 34.1 s, 34.2 s, 34.3 s, 34.4 s, 34.5 s, 34.6 s, 34.7 s, 34.8 s, 34.9 s, 35 s, 35.1 s, 35.2 s, 35.3 s, 35.4 s, 35.5 s, 35.6 s, 35.7 s, 35.8 s, 35.9 s, 36 s, 36.1 s, 36.2 s, 36.3 s, 36.4 s, 36.5 s, 36.6 s, 36.7 s, 36.8 s, 36.9 s, 37 s, 37.1 s, 37.2 s, 37.3 s, 37.4 s, 37.5 s, 37.6 s, 37.7 s, 37.8 s, 37.9 s, 38 s, 38.1 s, 38.2 s, 38.3 s, 38.4 s, 38.5 s, 38.6 s, 38.7 s, 38.8 s, 38.9 s, 39 s, 39.1 s, 39.2 s, 39.3 s, 39.4 s, 39.5 s, 39.6 s, 39.7 s, 39.8 s, 39.9 s, 40 s, 40.1 s, 40.2s, 40.3s, 40.4s, 40.5s, 40.6s, 40.7s, 40.8s, 40.9s, 41s, 41.1s, 41.2s, 41.3s, 41.4s, 41.5s, 41.6s, 41.7s, 41.8s, 41.9s, 42s, 42.1s, 42.2s, 42.3s, 42.4s, 42.5s, 42.6s, 42.7s, 42.8s, 42.9s, 43s, 43.1 s, 43.2 s, 43.3 s, 43.4 s, 43.5 s, 43.6 s, 43.7 s, 43.8 s, 43.9 s, 44 s, 44.1 s, 44.2 s, 44.3 s, 44.4 s, 44.5 s, 44.6 s, 44.7 s, 44.8 s, 44.9 s, 45 s, 45.1 s, 45.2 s, 45.3 s, 45.4 s, 45.5 s, 45.6 s, 45.7 s, 45.8 s, 45.9 s, 46 s, 46.1 s, 46.2 s, 46.3 s, 46.4 s, 46.5 s, 46.6 s, 46.7 s, 46.8 s, 46.9 s, 47 s, 47.1 s, 47.2 s, 47.3 s, 47.4 s, 47.5 s, 47.6 s, 47.7 s, 47.8 s, 47.9 s, 48 s, 48.1 s, 48.2 s, 48.3 s, 48.4 s, 48.5 s, 48.6 s, 48.7 s, 48.8 s, 48.9 s, 49 s, 49.1 s, 49.2 s, 49.3 s, 49.4 s, 49.5 s, 49.6 s, 49.7 s, 49.8 s, 49.9 s, 50 s, 51 s, 52 s, 53 s, 54 s, 55 s, 56 s, 57 s, 58 s, 59 s, 60 s, 65 s, 70 s, 75 s, 80 s, 85 s, 90 s, 95 s, 100 s. Preferably, it can be more than 10 s and less than 60 s. More preferably, it can be more than 20 s and less than 50 s. More preferably, it can be more than 30 s and less than 50 s.

Also preferably, the method of applying the above ligand solution may be selected from the group consisting of spin coating, barcoding, nozzle printing, spray coating, slot die coating, gravure printing, inkjet printing, screen printing, electrohydrodynamic jet printing, and electrospray.

Also preferably, the above perovskite nanocrystals can have a crystal size equal to or greater than the exciton Bohr diameter (about 10 nm for MAPbBr3, about 7 nm for CsPbBr3, about 8 nm for FAPbBr3) and less than or equal to 30 nm. For example, it may be 7 nm, 7.5 nm, 8 nm, 8.3 nm, 8.5 nm, 8.7 nm, 9 nm, 9.3 nm, 9.5 nm, 9.7 nm, 10 nm, 10.3 nm, 10.5 nm, 10.7 nm, 11 nm, 11.3 nm, 11.5 nm, 11.7 nm, 12 nm, 12.3 nm, 12.5 nm,12.7 nm, 13 nm, 13.3 nm, 13.5 nm, 13.7 nm, 14 nm, 14.3 nm, 14.5 nm, 14.7 nm, 15 nm, 15.3 nm, 15.5 nm, 15. 7 nm, 16 nm, 16.5 nm 17 nm, 17.5 nm, 18 nm, 18.5 nm, 19 nm, 19.5 nm, 20 nm, 21 nm, 22 nm, 23 nm, 24 nm, 25 nm, 26 nm, 27 nm, 28 nm, 29 nm, 30 nm.

Preferably, it may be at least 7 nm and no more than 25 nm. More preferably, it may be more than 10 nm and less than 20 nm. More preferably, it may be more than 10 nm and less than or equal to 15 nm.

Further preferably, the above perovskite light-emitting material can emit light in the region of 300 nm to 1500 nm. More preferably, it can emit light in the region of 430 nm to 780 nm. More preferably, it can emit light in the region of 450 nm to 650 nm. For example, it may be 400 nm, 410 nm, 420 nm, 430 nm, 440 nm, 450 nm, 455 nm, 460 nm, 465 nm, 470 nm, 475 nm, 480 nm, 485 nm, 490 nm, 500 nm, 510 nm, 520 nm, 525 nm, 530 nm, 535 nm, 540 nm, 545 nm, 550 nm, 560 nm, 570 nm, 580 nm, 590 nm, 600 nm, 610 nm, 620 nm, 625 nm, 630 nm, 635 nm, 640 nm, 650 nm.

Further, to achieve the above third objective, the present inventive concept provides a perovskite light emitting device comprising a substrate, a first electrode located on the above substrate, a light-emitting layer located on the above first electrode, and a second electrode located on the above light-emitting layer, wherein the above light-emitting layer is a perovskite film having the in situ core/shell nanocrystal structure of claim 1.

Also preferably, the thickness of the above light-emitting layer may be from 10 nm to 10 μm.

Also preferably, the above first electrode or second electrode may comprise at least one selected from the group consisting of a metal, a conductive polymer, a metallic carbon nanotube, graphene, reduced graphene oxide, a metal nanowire, a carbon nanodot, a metal nanodot, and a conductive oxide, or a combination thereof.

Also preferably, the above light-emitting device may be selected from the group consisting of a light-emitting diode, a light-emitting transistor, a laser, and a polarized light-emitting device.

Further, to achieve the above third objective, the present inventive concept provides a perovskite light emitting device comprising a substrate; a first electrode located on the above substrate; a light-emitting layer located on the above first electrode; and a second electrode located on the above light-emitting layer, wherein the above light-emitting layer is the above perovskite light-emitting material.

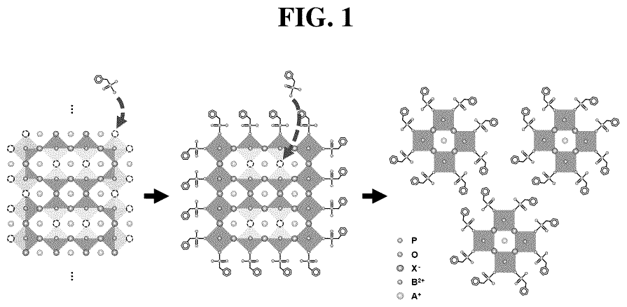

FIG. 1 illustrates a schematic of the synthesis of an in situ core/shell nanocrystal structure according to one embodiment of the present inventive concept.

Referring to FIG. 1, the perovskite film according to the present inventive concept initially has a polycrystalline structure with defect levels on the crystal surface and inside, an in situ particle structure with ligand self-assembled on the surface through reaction with the ligand, and an in situ core/shell nanocrystal structure where the crystal is broken into nanocrystal form and all internal defects are bound with the ligands.

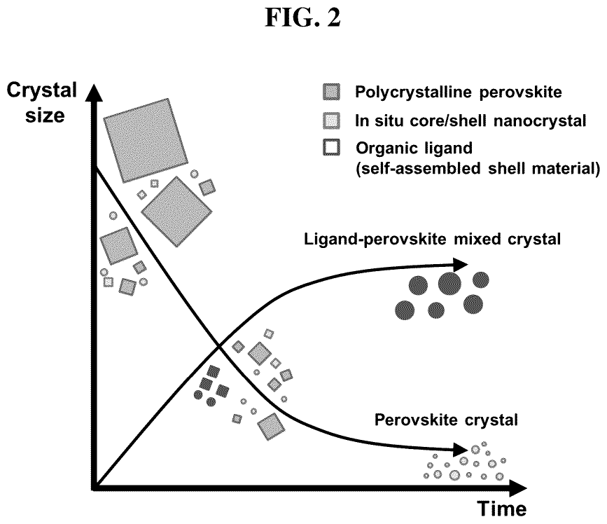

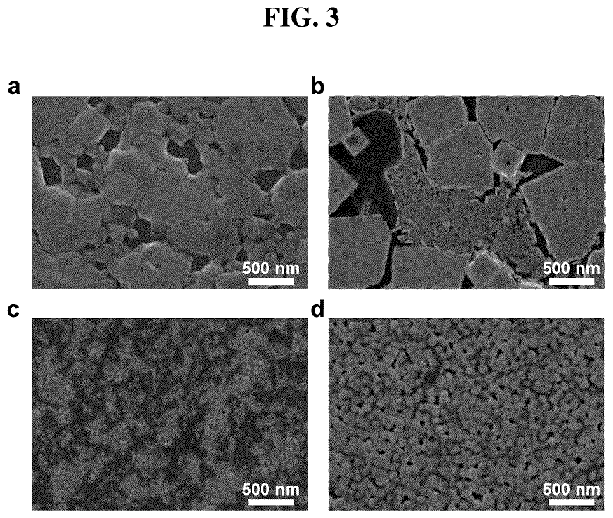

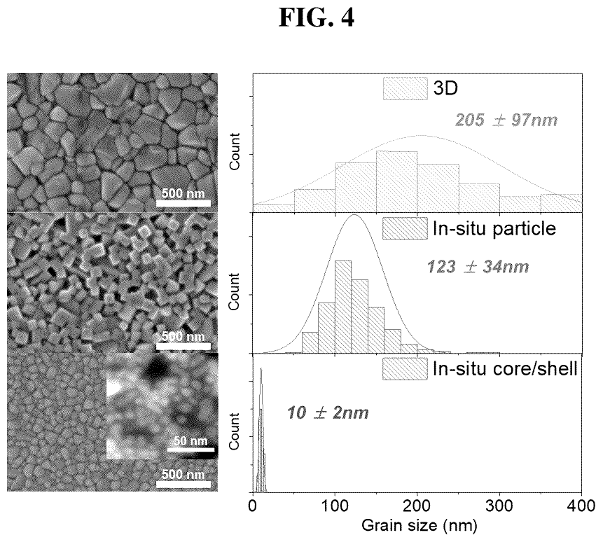

FIG. 2-7 illustrate film morphology changes and crystal size changes in the process of forming the core/shell structure of a perovskite film according to one embodiment of the present inventive concept.

The principle of forming the core/shell structure of the perovskite film according to the present inventive concept is as follows.

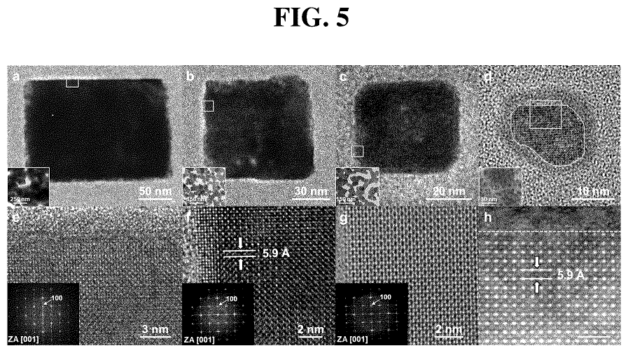

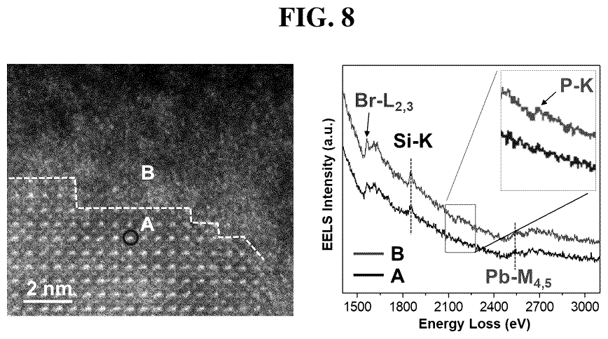

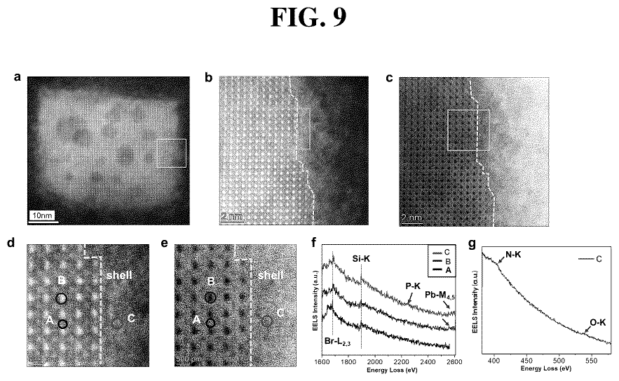

When polycrystalline perovskite films are formed by conventional techniques, ionic defects are present on the surface and inside the crystals, and when exposed to a ligand solution containing a polar solvent, the highly reactive defects present on the surface and inside the polycrystalline perovskite react and cause the crystal to split. The cleaved interface then acts as another defect surface on the crystal, and continued exposure to the ligand solution causes the crystal to continue to cleave and decrease in size until there are no more defects inside the cleavage. FIG. 5-7 are high magnification transmission electron microscopy images of perovskite crystals undergoing this process of in situ nanocrystal formation, showing that large polycrystalline grains of the order of 200 nm have been split into nanocrystal grains of about 10 nm. At the same time, the ligand molecules contained in the ligand solution bind to the defect sites exposed during the reaction and stabilize the surface. It can also be seen from FIG. 8-9 that the perovskite core and the interface with the external ligand become increasingly aligned as the in situ core/shell nanocrystal structure is formed, and that the organic ligand containing phosphonate groups is aligned with the perovskite core in the EEL spectrum.

The size of the crystals of perovskite having an in situ core/shell nanocrystal structure in the perovskite film according to the present inventive concept may be from 10 nm to 1 μm, but is not limited thereto.

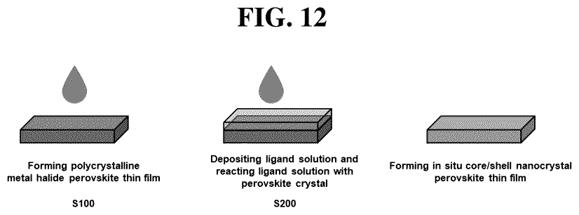

The perovskite film with the in situ core/shell nanocrystal structure according to the present inventive concept shows a strong charge confinement effect of the nanocrystals, and the photoluminescence quantum efficiency and photoluminescence lifetime are significantly improved by stabilizing the surface defects with the shell (see FIG. 12-14). Therefore, the perovskite film having an in situ core/shell nanocrystal structure according to the present inventive concept can be usefully employed in the light-emitting layer of a light emitting device.

### Preparation Method of Perovskite Film With In Situ Core/Shell Nanocrystal Structure

The present inventive concept also provides a method of preparing a perovskite film having an in situ core/shell nanocrystal structure.

A method of preparing a perovskite film having an in situ core/shell nanocrystal structure of the present inventive concept includes the steps of applying a ligand solution to a polycrystalline perovskite film S100 and preparing a perovskite film having an in situ core/shell nanocrystal structure through a reaction between the above perovskite bulk film and the ligand solution S200.

Hereinafter, the inventive concept will be described step by step.

First, step S100 is to prepare a polycrystalline perovskite film.

The polycrystalline perovskite precursor solution can be formed by dissolving AX and BX₂ in a solvent in a certain ratio. For example, a perovskite bulk precursor solution containing ABX₃ perovskite can be prepared by dissolving AX and BX₂ in a 1.06:1 ratio.

The solvent used in the preparation of the above perovskite bulk precursor solution may include dimethylformamide, gamma butyrolactone, N-methylpyrrolidone or dimethylsulfoxide, and combinations thereof.

The concentration of the perovskite bulk precursor solution may be from 0.01 M to 1.5 M. If the concentration of the perovskite bulk precursor solution is less than 0.01 M, there is a problem that the low concentration does not completely cover the substrate to be coated and the flatness is poor, making the device inoperable due to leakage current when applied as a light-emitting device, and if the concentration exceeds 1.5 M, there is a problem that the high concentration causes the crystals to agglomerate during the process of forming a thin film, making the crystals larger and having a rough surface.

Next, step S200 comprises applying the above ligand solution to the above polycrystalline perovskite film, providing a reaction time, and then coating to prepare a perovskite film having an in situ core/shell nanocrystal structure.

The member for applying the light-emitting layer may be a substrate, electrode, or semiconductor layer. The substrate, electrode, or semiconductor layer may be a substrate, electrode, or semiconductor layer that can be used in a light-emitting device. Furthermore, the member for applying the light-emitting layer may be a substrate/electrode stacked in a sequence or a substrate/electrode/semiconductor layer stacked in a sequence.

For a description of the above substrate, electrode, or semiconductor layer, reference is made to “Light emitting device comprising a perovskite film with an in situ core/shell nanocrystal structure” hereinafter.

The coating method may be selected from the group consisting of, but not limited to, spin coating, barcoding, nozzle printing, spray coating, slot die coating, gravure printing, inkjet printing, screen printing, electrohydrodynamic jet printing, and electrospray.

### Metal Halide Perovskite Light Emitting Device

According to one embodiment of the present inventive concept, the metal halide perovskites described above can be utilized in light emitting devices.

As used herein, “light-emitting device” can include any device that produces light, such as a light-emitting diode, light-emitting transistor, laser, or polarized light-emitting device.

The light-emitting device according to one embodiment of the present inventive concept is characterized in that it emits light from the aforementioned metal halide perovskite.

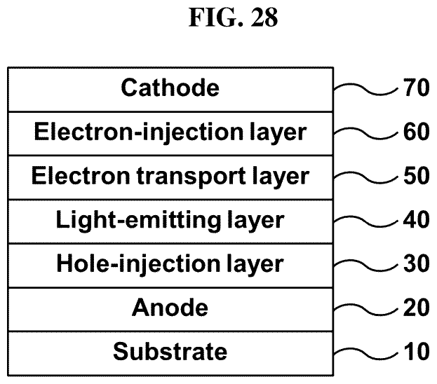

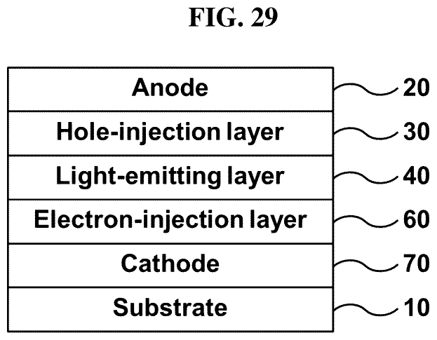

FIGS. 28 and 29 are schematic diagrams illustrating a light emitting device according to one embodiment of the present inventive concept.

Referring to FIGS. 28 and 29, a light emitting device according to the present inventive concept may comprise an anode 20 and a cathode 70, and a light-emitting layer 40 disposed between the two electrodes. Also preferably, between the above anode 20 and the above light-emitting layer 40, there may be a hole-injection layer 30 to facilitate the injection of holes. Furthermore, an electron transport layer 50 for transporting electrons and an electron-injection layer 60 for facilitating the injection of electrons can be provided between the above light-emitting layer 40 and the above cathode 70.

Further, the light emitting device according to the present inventive concept may further comprise a hole transport layer for transport of holes between the above hole-injection layer 30 and the above light-emitting layer 40.

Furthermore, a hole blocking layer (not shown) may be disposed between the light-emitting layer 40 and the electron transport layer 50. Furthermore, an electron blocking layer (not shown) may be disposed between the light-emitting layer 40 and the hole transport layer. However, without being limited thereto, the electron transport layer 50 may serve as the hole blocking layer, or the hole transport layer may serve as the electron blocking layer.

The anode 20 may be a conductive metal oxide, metal, metal alloy, or carbon material. The conductive metal oxide may be ITO, AZO (Al-doped ZnO), GZO (Ga-doped ZnO), IGZO (In,Ga-doped ZnO), MZO (Mg-doped ZnO), Mo-doped ZnO, Al-doped MgO, Ga-doped MgO, F-doped SnO₂, Nb-doped TiO₂, or CuAlO₂, or a combination thereof. Suitable metals or metal alloys for the anode 20 may be Au and CuI. The carbon material may be graphite, graphene, or carbon nanotubes.

The cathode 70 is a conductive film having a lower work function than the anode 20, and can be formed using, for example, a metal such as aluminum, magnesium, calcium, sodium, potassium, indium, yttrium, lithium, silver, lead, cesium, or a combination of two or more thereof.

The anode 20 and cathode 70 may be formed using a sputtering method, a vapor deposition method, or an ion beam deposition method. The hole-injection layer 30, hole transport layer, light-emitting layer 40, hole blocking layer, electron transport layer 50, and electron-injection layer 60 can be formed independently of each other using a deposition or coating method, such as spraying, spin coating, dipping, printing, doctor blading, or electrophoresis.

The hole-injection layer 30 and/or hole transport layer are layers having a HOMO level between the work function level of the anode 20 and the HOMO level of the light-emitting layer 40, and function to increase the efficiency of hole injection or transport from the anode 20 to the light-emitting layer 40.

The hole-injection layer 30 or hole transport layer may include materials conventionally used as hole transport materials, and single layer may comprise different hole transport materials. The hole transport material may be, for example, mCP (N,Ndicarbazolyl-3,5-benzene); PEDOT:PSS (poly(3,4-ethylenedioxythiophene):Polystyrenesulfonate); NPD (N,N″-di(1-naphthyl)-N,N″-diphenylbenzidine); N,N″-Bis(3-methylphenyl)-N,N″-diphenylbenzidine(TPD); DNTPD (N⁴,N⁴-Bis[4-[bis(3-methylphenyl)amino phenyl]-N⁴, N⁴-diphenyl-[1,1′biphenyl]-4,4′-diamine); N,N′-diphenyl-N,N′-dinaphthyl-4,4′-diaminobiphenyl; N,N,N′N′-tetra-p-tolyl-4,4′-diaminobiphenyl; N,N,N′N′-tetraphenyl-4,4′-diaminobiphenyl; derivatives of porphyrin compounds such as copper(II)1,10,15,20-tetraphenyl-21H,23H-porphyrin, etc; TAPC (1,1-Bis[4-N,N′-Di(p-tolyl)Amino]Phenyl]Cyclohexane); triarylamine derivatives such as N,N,N-tri(p-tolyl)amine, 4,4′, 4′-tris[N-(3-methylphenyl)-N-phenylamino]triphenylamine; carbazole derivatives such as N-phenylcarbazole and polyvinylcarbazole; phthalocyanine derivatives, such as metal-free phthalocyanines and copper phthalocyanines; starburst amine derivatives; enamine stilbene derivatives; derivatives of aromatic tertiary amines and styryl amine compounds; and polysilanes. These hole transport materials can also serve as an electronic blocking layer.

The hole-injection layer 30 may also include a hole-injection material. For example, the hole-injection layer 30 may comprise at least one of a metal oxide and a hole-injection organic material.

If the above hole-injection layer 30 comprises a metal oxide, the above metal oxide may be selected from the group consisting of MoO₃, WO₃, V₂O₅, Nickel Oxide (NiO), Copper Oxide (Copper(II) Oxide: CuO), Copper Aluminum Oxide (Copper Aluminum Oxide: CAO, CuAlO2), Zinc Rhodium Oxide (ZRO, ZnRh₂O₄), GaSnO, and one or more metal oxides selected from the group consisting of GaSnO doped with a metal-sulfide (FeS, ZnS, or CuS).

When the above hole-injection layer 30 comprises a hole-injection organic material, the above hole-injection layer 30 may be formed according to a method arbitrarily selected from various known methods, such as vacuum deposition method, spin coating method, casting method, Langmuir-Blodgett (LB) method, spray coating method, dip coating method, gravure coating method, reverse offset coating method, screen printing method, slot-die coating method, and nozzle printing method.

The above hole-injection organic materials may include at least one selected from the group consisting of Fullerene (C60), HAT-CN, F₁₆CuPC, CuPC, m-MTDATA [4,4′,4″-tris (3-methylphenylphenylamino) triphenylamine] (see formula below), NPB [N,N′-Di(1-naphthyl)-N,N″-diphenyl-(1,1′-biphenyl)-4,4′-diamine)], TDATA (see formula below), 2T-NATA (see formula below), P ani/D BSA (Polyaniline/Dodecylbenzenesulfonic 10 acid:Polyaniline/Dodecylbenzenesulfonic acid), PEDOT/PSS (Poly(3,4-ethylenedioxythiophene)/Poly(4-styrenesulfonate):Poly(3,4-ethylenedioxythiophene)/Poly(4-styrenesulfonate)), Pani/CSA (Polyaniline/Camphor sulfonicacid:Polyaniline/Camphor sulfonic acid), and PANI/PSS (Polyaniline/Poly(4-styrenesulfonate):Polyaniline)/Poly(4-styrenesulfonate)).

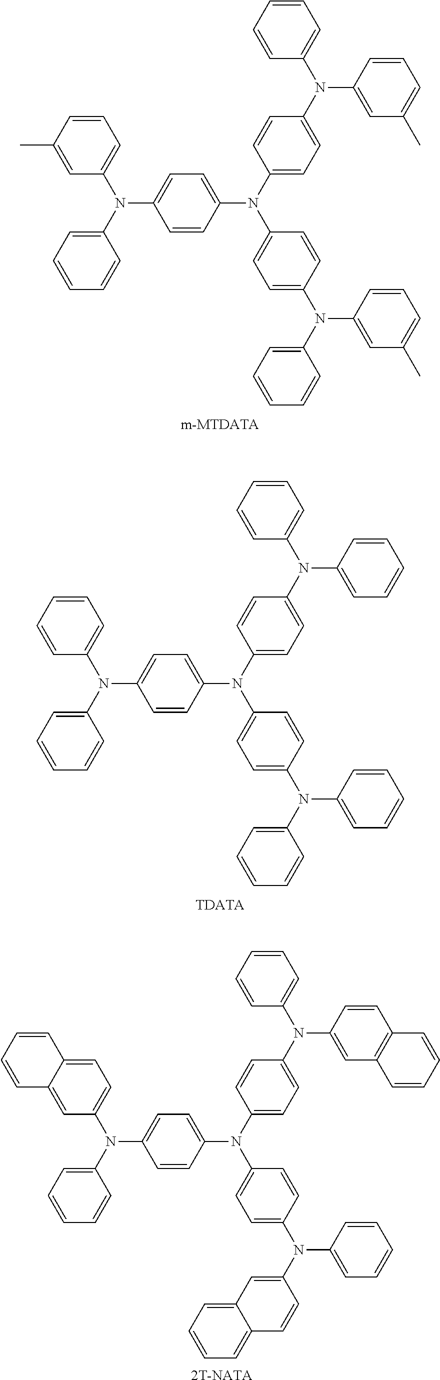

For example, the above hole-injection layer 30 may be a layer in which the above metal oxide is doped into the above hole-injection organic matrix. In this case, the doping concentration is preferably from 0.1 wt % to 80 wt %, based on the total weight of the hole-injection layer 30.

The thickness of the above hole-injection layer 30 may be from 1 nm to 1000 nm. For example, the thickness of the hole-injection layer 30 may be 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, 100 nm, 101 nm, 102 nm, 103 nm, 104 nm, 105 nm, 106 nm, 107 nm, 108 nm, 109 nm, 110 nm, 111 nm, 112 nm, 113 nm, 114 nm, 115 nm, 116 nm, 117 nm, 118 nm, 119 nm, 120 nm, 125 nm, 130 nm, 135 nm, 140 nm, 145 nm, 150 nm, 155 nm, 160 nm, 165 nm, 170 nm, 175 nm, 180 nm, 185 nm, 190 nm, 195 nm, 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 450 nm, 500 nm, 550 nm, 600 nm, 650 nm, 700 nm, 750 nm, 800 nm, 850 nm, 900 nm, 950 nm, 1000 nm, and may include the range between a lower limit value defined as the lower value of the two selected from the above numbers and an upper limit value defined as the higher value of the two. Also preferably, the thickness of the above hole-injection layer 30 may be from 10 nm to 200 nm. When the thickness of the hole-injection layer 30 satisfies the range as described above, the driving voltage is not substantially increased, and a high-performance organic device can be realized.

In addition, a hole transport layer may be further formed between the light-emitting layer and the hole-injection layer 30.

The hole transport layer may comprise a known hole transport material. For example, hole transport materials that may be included in the hole transport layer include at least one selected from the group consisting of 1,3-bis(carbazol-9-yl)benzene (1,3-bis(carbazol-9-yl)benzene: MCP), 1,3,5-tris(carbazol-9-yl)benzene (1,3,5-tris(carbazol-9-yl)benzene: TCP), 4,4′,4″-tris(carbazol-9-yptriphenylamine (4,4′,4″-tris(carbazol-9-yptriphenylamine: TCTA), 4,4′-bis(carbazol-9-yl)biphenyl (4,4′-bis(carbazol-9-yl)biphenyl: CBP), N,N′-bis(naphthalen-1-yl)-N,N′-bis(phenyl)benzidine (N,N′-bis(naphthalen-1-yl)-N,N′-bis(phenyl)-benzidine: NPB), N,N′-bis(naphthalen-2-yl)-N,N′-bis(phenyl)-benzidine (N,N′-bis(naphthalen-2-yl)-N,N′-bis(phenyl)-benzidine: β-NPB), N,N′-bis(naphthalen-1-yl)-N,N′-bis(phenyl)-2,2′-dimethylbenzidine (N,N′-bis(naphthalen-1-yl)-N,N′-bis(phenyl)-2,2′-dimethylbenzidine: α-NPD), Di-[4,-(N,N-ditolyl-amino)-phenyl]cyclohexane (Di-[4-(N,N-ditolyl-amino)-phenyl]cyclohexane: TAPC), N,N,N′,N′-tetra-naphthalen-2-yl-benzidine (N,N,N′,N′-tetra-naphthalen-2-yl-benzidine: β-TNB) and N4,N4,N4′,N4′-tetra(biphenyl-4-yl)biphenyl-4,4′-diamine (TPD15), poly(9,9-dioctylfluorene-co-bis-N,N′-(4-butylphenyl)-bis-N,N′-phenyl-1,4-phenylenediamine) (PFB), poly(9,9′-dioctylfluorene-co-N-(4-butylphenyl) diphenylamine) (TFB), poly(9,9′-dioctylfluorene-co-bis-N,N′-(4-butylphenyl)-bis-N,N′-phenylbenzidine) (BFB), poly(9,9-dioctylfluorene-co-bis-N,N′-(4-methoxyphenyl)-bis-N,N′-phenyl-1, and 4-phenylenediamine) (PFMO), but not limited thereto.

The chemical formulas of the above hole transport materials are summarized in Table 1 below.

TABLE 1

| | Chemical |
|---|---|
| Name | formulas |
| NPB | 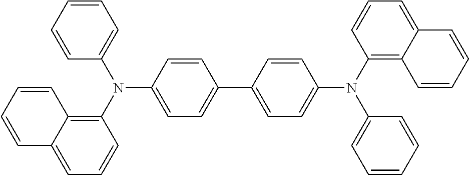 [SMILES: c1ccc(N(c2ccc(-c3ccc(N(c4ccccc4)c4cccc5ccccc45)cc3)cc2)c2cccc3ccccc23)cc1] |
| MCP | 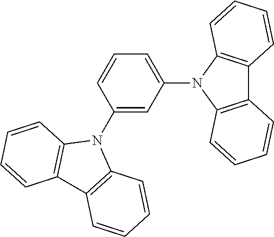 [SMILES: c1cc(-n2c3ccccc3c3ccccc32)cc(-n2c3ccccc3c3ccccc32)c1] |
| TCP | 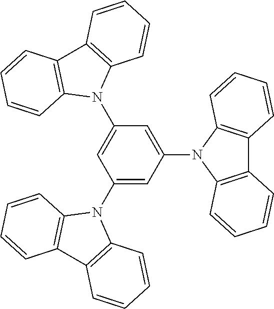 [SMILES: c1ccc2c(c1)c1ccccc1n2-c1cc(-n2c3ccccc3c3ccccc32)cc(-n2c3ccccc3c3ccccc32)c1] |
| TCTA | 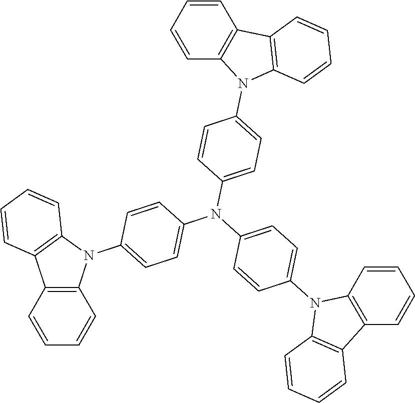 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1] |
| CBP | 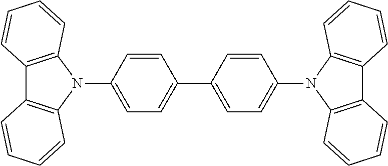 [SMILES: c1ccc2c(c1)c1ccccc1n2-c1ccc(-c2ccc(-n3c4ccccc4c4ccccc43)cc2)cc1] |
| ß-NPB | 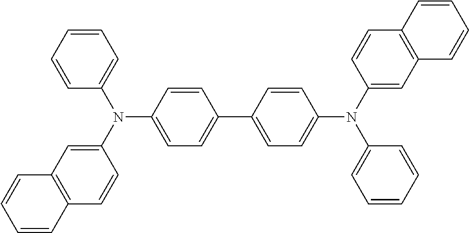 [SMILES: c1ccc(N(c2ccc(-c3ccc(N(c4ccccc4)c4ccc5ccccc5c4)cc3)cc2)c2ccc3ccccc3c2)cc1] |
| α-NPD | 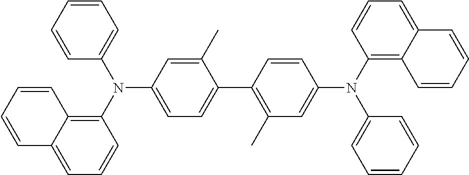 [SMILES: Cc1cc(N(c2ccccc2)c2cccc3ccccc23)ccc1-c1ccc(N(c2ccccc2)c2cccc3ccccc23)cc1C] |
| TAPC | 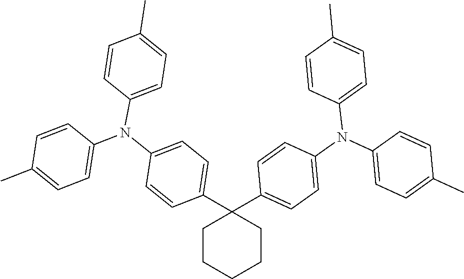 |
| ß-TNB | 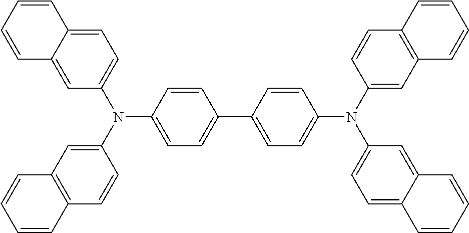 [SMILES: c1ccc2cc(N(c3ccc(-c4ccc(N(c5ccc6ccccc6c5)c5ccc6ccccc6c5)cc4)cc3)c3ccc4ccccc4c3)ccc2c1] |
| TPD15 | 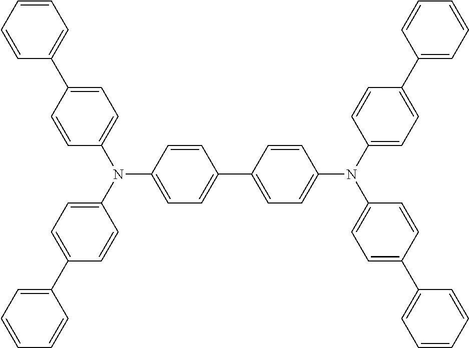 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1] |

One of the hole transport layers, e.g., TCTA, in addition to its hole transport role, may also play a role in preventing exciton diffusion from the light-emitting layer.

The thickness of the above hole transport layer may be from 1 nm to 100 nm. For example, the thickness of the hole transport layer may be 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, 100 nm, and may include the range between a lower limit value defined as the lower value of the two selected from the above numbers and an upper limit value defined as the higher value of the two. Also preferably, the thickness of the above hole transport layer may be from 10 nm to 60 nm. When the thickness of the hole transport layer satisfies the range as described above, the luminescence efficiency of the organic light emitting diode can be improved and the brightness can be increased.

The electron-injection layer 60 and/or the electron transport layer 50 are layers having a LUMO level between the work function level of the cathode 70 and the LUMO level of the light-emitting layer 40, and function to increase the efficiency of electron injection or transport from the cathode 70 to the light-emitting layer 40.

The electron-injection layer 60 may be, for example, LiF, NaCl, NaF, CsF, Li₂O, BaO, BaF₂, MgF₂, or Liq (lithium quinolate). In addition, the electron transport layer and the above electron injection layer material may be co-deposited to form a doped electron transport layer, which may replace the electron-injection layer 60.

The electron transport layer 50 may include a quinoline derivative such as tris(8-hydroxyquinoline) aluminum (Alq3), bis(2-methyl-8-quinolinolate)-4-(phenylphenolato)aluminum (Balq), and bis(10-hydroxybenzo[h]quinolinato)beryllium (Bebq₂), and it may include 2,9-dimethyl-4,7-diphenyl-1,10-phenanthroline (BCP), 4,7-diphenyl-1,10-phenanthroline (Bphen), 2,2′,2″-(benzene-1,3,5-triyl)-tris(1-phenyl-1H-benzimidazole) (TPBI), 3-(4-biphenyl)-4-(phenyl-5-tert-butylphenyl-1,2,4-triazole (TAZ), 4-(naphthalen-1-yl)-3,5-diphenyl-4H-1,2,4-triazole (NTAZ), 2,9-bis(naphthalen-2-yl)-4,7-diphenyl-1,10-phenanthroline (NBphen), tris(2,4,6-trimethyl-3-(pyridin-3-yl)phenyl)borane (3TPYMB), phenyl-dipyrenylphosphine oxide (POPy2), 3,3′,5,5t-tetra[(m-pyridyl)-phen-3-yl]biphenyl (BP4mPy), 1,3,5-triR3-pyridyl)-phen-3-yHbenzene (TmPyPB), 1,3-bis [3,5-dapyridin-3-yl)phenyl]benzene (BmPyPhB), bis(10-hydroxybenzo[h]quinolinato)beryllium (Bepq2), diphenylbis(4-(pyridin-3-yl)phenyl)silane (DPPS) and 1,3,5-tri(p-pyrid-3-yl-phenyl)benzene (1,3,5-tri(p-pyrid-3-yl-phenyl)benzene: TpPyPB), 1,3-bis[2-(2,2′-bipyridine-6-yl)-1,3,4-oxadiazo-5-yl]benzene (Bpy-OXD), 6,6′-bis[5-(biphenyl-4-yl)-1,3,4-oxadiazo-2-yl]-2,2′-bipyridyl (BP-OXD-Bpy), diphenylphosphine 5 oxide-4-(triphenylsilyl)phenyl(TSPO1), 1,3,5-tris(N-phenylbenzimidazol-2-yl)benzene(TPBO, tris(8-quinolinolate)aluminum (Alq₃), 2,5-diaryl silol derivatives (PyPySPyPy), perfluorinated compounds (PF-6P), and octasubstituted cyclooctatetraenes (COTs).The chemical formulas of the above electron transport materials are summarized in Table 2 below.

TABLE 2

| | Chemical |
|---|---|
| Name | formulas |
| Alq₃ | 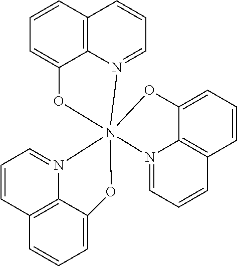 |
| TPBI | 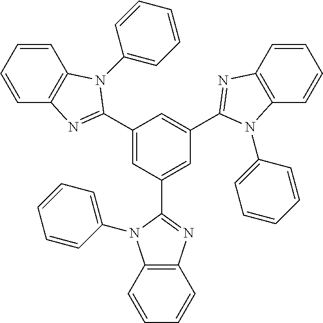 [SMILES: c1ccc(-n2c(-c3cc(-c4nc5ccccc5n4-c4ccccc4)cc(-c4nc5ccccc5n4-c4ccccc4)c3)nc3ccccc32)cc1] |
| PBD | 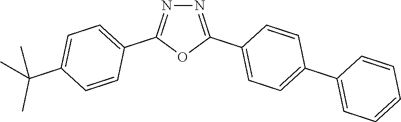 [SMILES: CC(C)(C)c1ccc(-c2nnc(-c3ccc(-c4ccccc4)cc3)o2)cc1] |
| BCP | 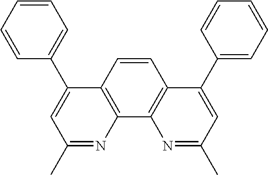 [SMILES: Cc1cc(-c2ccccc2)c2ccc3c(-c4ccccc4)cc(C)nc3c2n1] |
| Bphen | 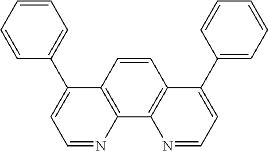 [SMILES: c1ccc(-c2ccnc3c2ccc2c(-c4ccccc4)ccnc23)cc1] |
| Balq | 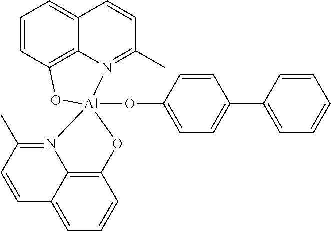 |
| Bpy-OXD | 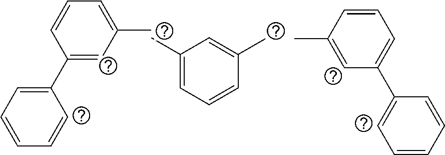 |
| BP-OXD-Bpy | 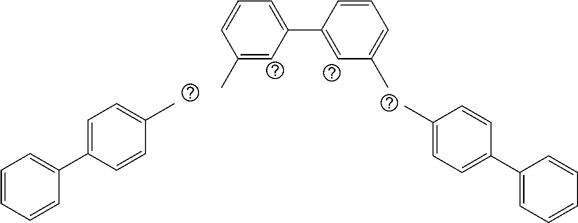 |
| TAZ | 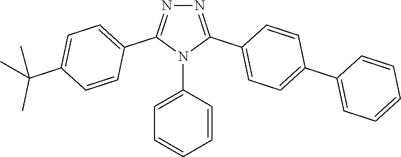 [SMILES: CC(C)(C)c1ccc(-c2nnc(-c3ccc(-c4ccccc4)cc3)n2-c2ccccc2)cc1] |
| NTAZ | 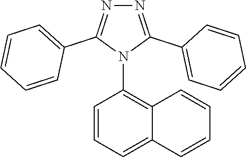 [SMILES: c1ccc(-c2nnc(-c3ccccc3)n2-c2cccc3ccccc23)cc1] |
| NBphen | 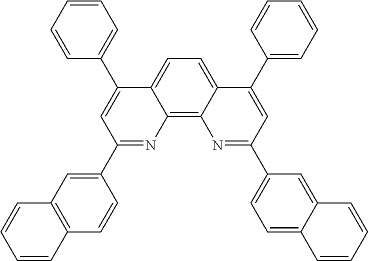 [SMILES: c1ccc(-c2cc(-c3ccc4ccccc4c3)nc3c2ccc2c(-c4ccccc4)cc(-c4ccc5ccccc5c4)nc23)cc1] |
| 3TPYMB | 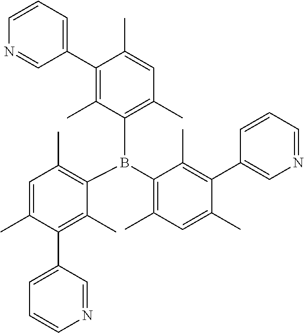 [SMILES: Cc1cc(C)c(-c2cccnc2)c(C)c1B(c1c(C)cc(C)c(-c2cccnc2)c1C)c1c(C)cc(C)c(-c2cccnc2)c1C] |
| POPy₂ | 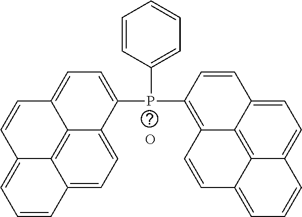 |
| BP4mPy | 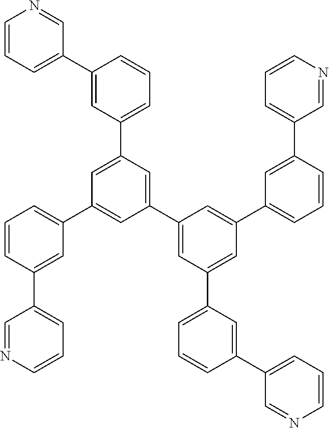 [SMILES: c1cncc(-c2cccc(-c3cc(-c4cccc(-c5cccnc5)c4)cc(-c4cc(-c5cccc(-c6cccnc6)c5)cc(-c5cccc(-c6cccnc6)c5)c4)c3)c2)c1] |
| TmPyPB | 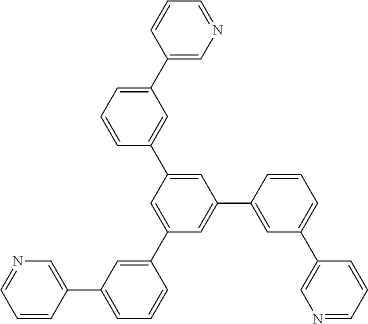 [SMILES: c1cncc(-c2cccc(-c3cc(-c4cccc(-c5cccnc5)c4)cc(-c4cccc(-c5cccnc5)c4)c3)c2)c1] |
| BmPyPhB | 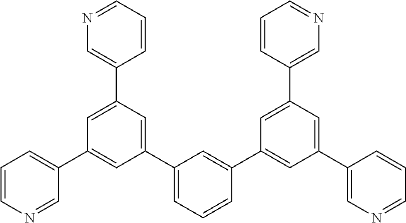 [SMILES: c1cncc(-c2cc(-c3cccnc3)cc(-c3cccc(-c4cc(-c5cccnc5)cc(-c5cccnc5)c4)c3)c2)c1] |
| Bebq₂ | 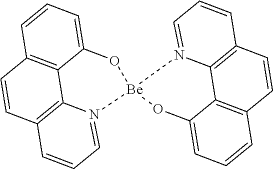 |
| DPPS | 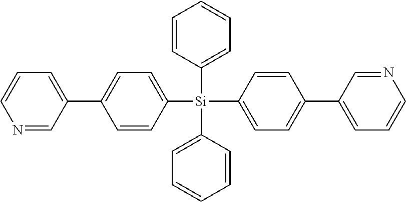 [SMILES: c1ccc([Si](c2ccccc2)(c2ccc(-c3cccnc3)cc2)c2ccc(-c3cccnc3)cc2)cc1] |
| TpPyPB | 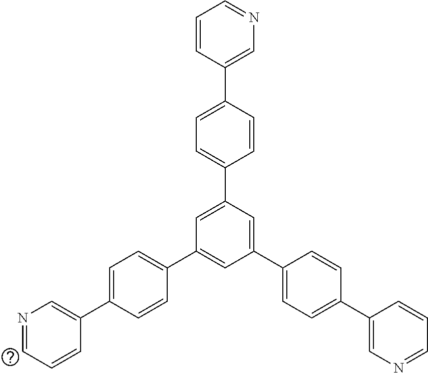 [SMILES: c1cncc(-c2ccc(-c3cc(-c4ccc(-c5cccnc5)cc4)cc(-c4ccc(-c5cccnc5)cc4)c3)cc2)c1] |

The thickness of the electron transport layer 50 may be from about 5 nm to 100 nm. For example, the thickness of the electron transport layer 50 may be 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, 100 nm, and may include the range between a lower limit value defined as the lower value of the two selected from the above numbers and an upper limit value defined as the higher value of the two. Also preferably, the thickness of the above electron transport layer 50 may be from 15 nm to 60 nm. When the thickness of the electron transport layer 50 satisfies the range as described above, excellent electron transport characteristics can be obtained without increasing the drive voltage. The electron-injection layer 60 may comprise a metal oxide. The metal oxide may be selected from semiconductor materials having n-type semiconductor properties, which have excellent electron transport capability, and furthermore are not reactive to air or moisture and have excellent transparency in the visible light region.

The electron-injection layer 60 may be one or more metal oxides selected from, for example, an aluminum doped zinc oxide (Aluminum doped zinc oxide; AZO), AZO doped with an alkali metal (Li, Na, K, Rb, Cs, or Fr), TiOₓ (where x is a real number from 1 to 3), indium oxide (In₂O₃), tin oxide (SnO₂), zinc oxide (ZnO), and zinc tin oxide (ZTO), gallium oxide (Ga₂O₃), tungsten oxide (WO₃), aluminum oxide, titanium oxide, vanadium oxide (V₂O₅, vanadium(IV) oxide (VO₂), V₄O₇, V₅O₉, or V₂O₃), molybdenum oxide (MoO₃ or MoOₓ), copper oxide (Copper(II) Oxide: CuO), nickel oxide (NiO), copper aluminum oxide (CAO, CuAlO₂), zinc rhodium oxide (ZRO, ZnRh₂O₄), iron oxide, chromium oxide, bismuth oxide, indium-gallium zinc oxide (IGZO), and ZrO₂, but not limited thereto. In one example, the electron-injection layer 60 may be a metal oxide thin film layer, a metal oxide nanoparticle layer, or a layer containing metal oxide nanoparticles within a metal oxide thin film.

The electron-injection layer 60 may be formed using a wet process or a vapor deposition method.

If the above electron-injection layer 60 is formed by a solution method (e.g., sol-gel method), as an example of a wet process, a mixture for the electron-injection layer 60 comprising at least one of a sol-gel precursor of a metal oxide and a metal oxide in nanoparticle form and a solvent may be applied to the above substrate 10 and then heat treated to form the above electron-injection layer 60. At this time, the solvent may be removed by the heat treatment, or the electron-injection layer 60 may be crystallized. The method of providing the mixture for the electron-injection layer 60 onto the substrate 10 may be selected from, but not limited to, the coating methods disclosed, such as spin coating, casting, Langmuir-Blodgett (LB) method, spray coating, dip coating, gravure coating, reverse offset coating, screen printing, slot-die coating and nozzle printing, and dry transfer printing.

Sol-gel precursors of the above metal oxides include metal salts (e.g., metal halides, metal sulfates, metal nitrates, metal perchlorates, metal acetates, metal carbonates, and the like), metal salt hydrides, metal hydroxides, metal alkyls, metal alkoxides, metal carbides, metal acetylacetonate, metal acid, metal salt, metal salt hydrate, metal sulfide, metal acetate, metal alkanoate, metal phthalocyanine, metal nitrate, and metal carbonate, and may contain at least one selected from the group consisting of.

When the metal oxide is ZnO, the ZnO sol-gel precursors are zinc sulfate, zinc fluoride, zinc chloride, zinc bromide, zinc iodide, zinc perchlorate, zinc hydroxide (Zn(OH)₂), zinc acetate (Zn(CH₃COO)₂), zinc acetate hydrate (Zn(CH₃(COO)₂nH₂O), diethyl zinc (Zn(CH₃CH₂)₂), zinc nitrate (Zn(NO₃)₂), zinc nitrate hydrate (Zn(NO₃)₂nH₂O), zinc carbonate (Zn(CO₃)), zinc acetylacetonate (Zn(CH₃COCHCOCH₃)₂), and zinc acetylacetonate hydrate (Zn(CH₃COCHCOCH₃)₂nH₂O)), at least one selected from the group consisting of, but not limited to.

If the metal oxide is indium oxide (In₂O₃), the In₂O₃ sol-gel precursor is indium nitrate (ₙH₂O), indium acetate (In(CH₃COO)₂), indium acetate hydrate (In(CH₃(COO)₂nH₂O), indium chloride (InCl, InCl₂, InCl₃), indium nitrate (In(NO₃)₃), indium nitrate hydrate (In(NO₃)₃nH₂O), indium acetylacetonate (In(CH₃COCHCOCH₃)₂), and indium acetylacetonate hydrate (In(CH₃COCHCOCH₃)₂nH₂O).

If the metal oxide is tin oxide (SnO₂), the SnO₂ sol-gel precursor is tin acetate (Sn(CH₃COO)₂), tin acetate hydrate (Sn(CH₃(COO)₂ₙH₂O), tin chloride (SnCl₂, SnCl₄), tin chloride hydrate (SnClₙnH₂O), at least one selected from the group consisting of tin acetylacetonate (Sn(CH₃COCHCOCH₃)₂), and tin acetylacetonate hydrate (Sn(CH₃COCHCOCH₃)₂nH₂O).

When the above metal oxide is gallium oxide (Ga₂O₃), the Ga₂O₃ sol-gel precursor can be at least one selected from the group consisting of gallium nitrate (Ga(NO₃)₃), gallium nitrate hydrate (Ga(NO₃)₃nH₂O), gallium acetylacetonate (Ga(CH₃COCHCOCH₃)₃), gallium acetylacetonate hydrate (Ga(CH₃COCHCOCH₃)₃nH₂O), and gallium chloride (Ga₂Cl₄, GaCl₃).

If the metal oxide is tungsten oxide (WO₃), the WO₃ sol-gel precursor is tungsten carbide (WC), tungstic acid powder (H₂WO₄), tungsten chloride (WCl₄, WCl₆), tungsten isopropoxide (W(OCH(CH₃)₂)₆), sodium tungstate (Na₂WO₄), sodium tungstate hydrate (Na₂WO₄nH₂O), ammonium tungstate ((NH₄)₆H₂ W₁₂O₄₀, ammonium tungstate hydrate ((NH₄)₆H₂W₁₂O₄₀nH₂O), and tungsten ethoxide (W(OC₂H₅)₆).

When the above metal oxide is aluminum oxide, the aluminum oxide sol-gel precursor can be at least one selected from the group consisting of aluminum chloride (AlCl₃), aluminum nitrate (Al(NO₃)₃), aluminum nitrate hydrate (Al(NO₃)₃·nH₂O), and aluminum butoxide (Al(C₂H₅CH(CH₃)O)).

When the above metal oxide is titanium oxide, the titanium oxide sol-gel precursor can be at least one selected from the group consisting of titanium isopropoxide (Ti(OCH(CH₃)₂)₄), titanium chloride (TiCl₄), titanium ethoxide (Ti(OC₂H₅)₄), and titanium butoxide (Ti(OC₄H₉)₄).

When the above metal oxide is vanadium oxide, the sol-gel precursor of vanadium oxide can be at least one selected from the group consisting of vanadium isopropoxide (VO(OC₃H₇)₃), ammonium vanadate (NH₄VO₃), vanadium acetylacetonate (V(CH₃COCHCOCH₃)₃), and vanadium acetylacetonate hydrate (V(CH₃COCHCOCH₃)₃·nH₂O).

When the above metal oxide is molybdenum oxide, the molybdenum oxide sol-gel precursor can be at least one selected from the group consisting of molybdenum isopropoxide (Mo(OC₃H₇)₅), molybdenum chloride isopropoxide (MoCl₃(OC₃H₇)₂), ammonium molybdate ((NH₄)₂MoO₄), and ammonium molybdate hydrate ((NH₄)₂MoO₄nH₂O).

When the metal oxide is copper oxide, the copper oxide sol-gel precursors are copper chloride (CuCl, CuCl₂), copper chloride hydrate (CuCl₂nH₂O), copper acetate (Cu(CO₂CH₃), Cu(CO₂CH₃)₂), copper acetate hydrate (Cu(CO₂CH₃)₂·nH₂O), copper acetylacetonate (Cu(C₅H₇O₂)₂), copper nitrate (Cu(NO₃)₂), copper nitrate hydrate (Cu(NO₃)₂·nH₂O), copper bromide (CuBr, CuBr₂), copper carbonate (CuCO₃Cu(OH)₂), copper sulfide (Cu₂S, CuS), copper phthalocyanine (C₃₂H₁₆N₈Cu), copper trifluroacetate (Cu(CO₂CF₃)₂), copper isobutyrate (C₈H₁₄CuO₄), copper ethylacetoacetate (C₁₂H₁₈CuO₆), copper 2-ethylhexanoate ([CH₃(CH₂)₃CH(C₂H₅)CO₂]₂Cu), copper fluoride (CuF₂), copper formate ((HCO₂)₂CuH₂O), copper gluconate (C₁₂H₂₂CuO₁₄), copper hexafluoroacetylacetonate (Cu(C₅HF₆O₂)₂), copper hexafluoroacetylacetonate hydrate (Cu(C₅HF₆O₂)₂nH₂O), copper methoxide (Cu(OCH₃)₂), copper neodecanoate (C₁₀H₁₉O₂Cu), copper perchlorate (Cu(ClO₄)₂·6H₂O), copper sulfate (CuSO₄), copper sulfate hydrate (CuSO₄·nH₂O), copper tartrate hydrate ([⁻CH(OH)CO₂]₂CunH₂O), copper trifluroacetylacetonate (Cu(C₅H₄F₃O₂)₂), copper trifloromethanesulfonate ((CF₃SO₃)₂Cu), and tetraamine copper sulfate hydrate (Cu(NH₃)₄SO₄H₂O).

When the metal oxide is nickel oxide, the nickel oxide sol-gel precursors are nickel chloride (NiCl₂), nickel chloride hydrate (NiCl₂nH₂O), nickel acetate hydrate (Ni(OCOCH₃)₂·4H₂O), nickel nitrate hydrate (Ni(NO₃)₂·6H₂O), at least one selected from the group consisting of nickel acetylacetonate (Ni(C₅H₇O₂)₂), nickel hydroxide (Ni(OH)₂), nickel phthalocyanine (C₃₂H₁₆N₈Ni), and nickel carbonate hydrate (NiCO₃2Ni(OH)₂·nH₂O).

When the metal oxide is iron oxide, the sol-gel precursors of iron oxide are ferric acetate (Fe(CO₂CH₃)₂), ferric chloride (FeCl₂, FeCl₃), ferric chloride (FeCl₃·nH₂O), iron acetylacetonate (Fe(C₅H₇O₂)₃), ferric nitrate (Fe(NO₃)₃9H₂O), iron phthalocyanine (C₃₂H₁₆FeN₈), iron oxalate hydrate (Fe(C₂O₄)·nH₂O), and Fe₂(C₂O₄)₃·6H₂O).

When the metal oxide is chromium oxide, the chromium oxide sol-gel precursors are chromium chloride (CrCl₂, CrCl₃), chromium chloride hydrate (CrCl₃·nH₂O), chromium carbide (Cr₃C₂), chromium acetylacetonate (Cr(C₅H₇O₂)₃), chromium nitrate (Cr(NO₃)₃·nH₂O), chromium hydroxide (CH₃CO₂)₇Cr₃(OH)₂), and chromium acetate hydrate ([(CH₃CO₂)₂CrH₂O]₂) selected from the group consisting of.

When the above metal oxide is bismuth oxide, the bismuth oxide sol-gel precursor can be at least one selected from the group consisting of bismuth chloride (BiCl₃), bismuth nitrate hydrate (Bi(NO₃)₃·nH₂O), bismuth acetic acid ((CH₃CO₂)₃Bi), and bismuth scavonate ((BiO)₂CO₃).

When the above mixture for the electron-injection layer 60 contains metal oxide nanoparticles, the above metal oxide nanoparticles may have an average particle diameter of 10 nm to 100 nm.

The solvent may be a polar solvent or a non-polar solvent. For example, examples of polar solvents include alcohols, ketones, and the like, and examples of non-polar solvents include aromatic hydrocarbons, alicyclic hydrocarbons, and aliphatic hydrocarbon-based organic solvents. In one example, the above solvent is ethanol, dimethylformamide, ethanol, methanol, propanol, butanol, isopropanol. The solvent may be one or more selected from, but not limited to, methyl ethyl ketone, propylene glycol (mono)methyl ether (PGM), isopropyl cellulose (IPC), ethylene carbonate (EC), methylcellosolve (MC), ethylcellosolve, 2-methoxyethanol, and ethanolamine.

For example, when forming an electron-injection layer 60 comprising ZnO, the mixture for the electron-injection layer 60 may include, but is not limited to, zinc acetate dehydrate as a precursor to ZnO and a combination of 2-methoxyethanol and ethanolamine as a solvent.

The above heat treatent conditions will vary depending on the type and content of the selected solvent, but are generally preferably performed within the range of 100° C. to 350° C. and 0.1 hour to 1 hour. If the above heat treatment temperature and time satisfy this range, the solvent removal effect is good and the device may not be deformed.

If the electron-injection layer 60 is formed using a deposition method, it can be deposited by various methods known in the technical field, such as electron beam deposition, thermal evaporation, sputter deposition, atomic layer deposition, chemical vapor deposition, and the like. The deposition conditions depend on the target compound, the structure and thermal properties of the layer to be deposited, and the like, but are preferably performed within a deposition temperature range of 25 to 1500° C., more particularly 100 to 500° C., a vacuum range of 10⁻¹⁰ to 10⁻³ torr, and a deposition rate range of 0.01 to 100 Å/sec.

The thickness of the above electron-injection layer 60 may be from 1 nm to 100 nm. For example, the thickness of the above electron-injection layer 60 may be 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, 100 nm, and may include the range between a lower limit value defined as the lower value of the two selected from the above numbers and an upper limit value defined as the higher value of the two. Also preferably, the thickness of the above electron-injection layer 60 may be from 15 nm to 60 nm.

The hole-injection layer 30, hole transport layer, electron-injection layer 60, or electron transport layer 50 may be any of the materials used in conventional organic light emitting diodes.

The hole-injection layer 30, hole transport layer, electron-injection layer 60, or electron transport layer 50 may be formed by performing a method arbitrarily selected from various known methods, such as vacuum deposition, spin coating, spraying, dip coating, bar coating, nozzle printing, slot-die coating, gravure printing, casting, or Langmuir-Blodgett (LB) film method. At this time, the conditions for forming the thin film and the coating conditions may vary depending on the target compound, the structure, and thermal properties of the target layer, etc.

The substrate 10 is a support for the light-emitting device, and may be a transparent material. Furthermore, the substrate 10 may be a flexible material or a rigid material, preferably a flexible material.

The material of the above substrate 10 may be glass, sapphire, quartz, silicon, polyethylene terephthalate (PET), polystyrene (PS), polyimide (PI), polyvinyl chloride (PVC), polyvinylpyrrolidone (PVP), or polyethylene (PE).

The substrate 10 may be disposed below the anode 20 or above the cathode 70. In other words, the anode 20 may be formed before the cathode 70 on the substrate, or the cathode 70 may be formed before the anode 20. Thus, the light-emitting device may have both the forward structure of FIG. 28 and the reverse structure of FIG. 29.

The light-emitting layer 40 is formed between the hole-injection layer 30 and the electron-injection layer 60, and plays a role in causing light emission by combining holes (H) introduced from the anode 20 and electrons (E) introduced from the cathode 70 to form excitons, and emitting light as the excitons transition to the ground state.

In the light emitting device according to the inventive concept, the light-emitting layer 40 is characterized in that it comprises a metal halide perovskite as described above.

The metal halide perovskite may be a material having a three-dimensional crystal structure or a two-dimensional crystal structure or a one-dimensional crystal structure or a zero-dimensional crystal structure.

The metal halide perovskite may comprise the structure ABX₃ (3D), A₄BX₆ (0D), AB₂X₅ (2D), A₂BX₄ (2D), A₂BX₆ (0D), A₂B⁺B³⁺X₆(3D), A₃B₂X₉ (2D) or Aₙ₋₁BₙX₃ₙ₊₁ (quasi-2D), wherein n is an integer between 2 and 6. A may be a monovalent cation, B may be a metal, and X may be a halogen element. Specific examples of A, B and X of the above metal halide perovskites are as described in the above specification.

### Light Emitting Device Comprising a Perovskite Film With an In Situ Core/Shell Nanocrystal Structure

The present inventive concept also provides a perovskite light-emitting device comprising a perovskite film having the above in situ core/shell nanocrystal structure as a light-emitting layer 40.

The light-emitting device may be selected from the group consisting of a light-emitting diode, a light-emitting transistor, a laser, and a polarized light-emitting device.

FIG. 29 is a schematic illustration of a light emitting device according to one embodiment of the present inventive concept.

Referring to FIG. 29, a light emitting device according to the present inventive concept includes a substrate 10, a first electrode 20, a light-emitting layer 40, and a second electrode.

The substrate 10 is a support for the light-emitting device, and may be a transparent material. Furthermore, the substrate 10 may be a flexible material or a rigid material, preferably a flexible material. For example, the material of the substrate 10 may be, in particular, polyethylene terephthalate (PET), polystyrene (PS), polyimide (PI), polyvinyl chloride (PVC), polyvinylpyrrolidone (PVP), or polyethylene (PE).

A first electrode may be located on the above substrate 10.

The first electrode may be, but is not limited to, a conductive polymer or a conductive metal oxide such as ITO or FTO. For example, the first electrode may comprise at least one selected from the group consisting of a metal, a conductive polymer, a metallic carbon nanotube, graphene, reduced graphene oxide, a metal nanowire, a carbon nanodot, a metal nanodot, and a conductive oxide, or a combination thereof.

If a conductive polymer is used as the first electrode, the perovskite light-emitting layer 40 can be formed directly on the first electrode without further deposition of a hole-injection layer 30. On the other hand, if a type of electrode other than a conductive polymer is used as the first electrode, it may be necessary to introduce a hole-injection layer 30 on the first electrode.

For example, the above first electrode, which is the electrode into which the holes are injected, may comprise a material of a conductive nature. For example, the material comprising the first electrode may be a metal oxide. More specifically, it may be a transparent conductive metal oxide. For example, the transparent conductive metal oxide may be ITO, AZO (Al-doped ZnO), GZO (Ga-doped ZnO), IGZO (In,Ga-doped ZnO), MZO (Mg-doped ZnO), Mo-doped ZnO, Al-doped MgO, Ga-doped MgO, F-doped SnO₂, Nb-doped TiO₂, or CuAlO₂.

On the other hand, a hole-injection layer 30 may be further located on the first electrode. The hole-injection layer 30 may comprise a hole-transporting material, for example, 1,3-bis(carbazol-9-yl)benzene (1,3-bis(carbazol-9-yl)benzene: MCP), 1,3,5-tris(carbazol-9-yl)benzene (1,3,5-tris(carbazol-9-yl)benzene: TCP), 4,4′,4″-tris(carbazol-9-yptriphenylamine (4,4′,4″-tris(carbazol-9-yl)triphenylamine: TCTA), 4,4′-bis(carbazol-9-yl)biphenyl (4,4′-bis(carbazol-9-yl)biphenyl: CBP), N,N′-bis(naphthalen-1-yl)-N,N′-bis(phenyl)benzidine (N,N′-bis(naphthalen-1-yl)-N,N′-bis(phenyl)-benzidine: NPB), N,N′-bis(naphthalen-2-yl)-N,N′-bis(phenyl)-benzidine (N,N′-bis(naphthalen-2-yl)-N,N′-bis(phenyl)-benzidine: β-NPB), N,N′-bis(naphthalen-1-yl)-N,N′-bis(phenyl)-2,2′-dimethylbenzidine (N,N′-bis(naphthalen-1-yl)-N,N′-bis(phenyl)-2,2′-dimethylbenzidine: α-NPD), Di-[4,-(N,N-ditolyl-amino)-phenyl]cyclohexane (Di-[4-(N,N-ditolyl-amino)-phenyl]cyclohexane: TAPC), N,N,N′,N′-tetra-naphthalen-2-yl-benzidine (N,N,N′,N′-tetra-naphthalen-2-yl-benzidine: β-TNB) and N4,N4,N4′,N4′-tetra(biphenyl-4-yl)biphenyl-4,4′-diamine (TPD15) are examples, but not limited to.

Subsequently, a light-emitting layer 40 may be located on the above first electrode or on the above hole-injection layer 30. In this case, the above light-emitting layer 40 is characterized in that it is a perovskite film having the above in situ core/shell crystal structure. Since the manufacturing method of the perovskite film having the above-mentioned in situ core/shell crystal structure is as described above, it will be omitted to avoid redundancy.

The thickness of the above light-emitting layer 40 may be from 10 nm to 10 μm.

In the present inventive concept, an electron transport layer 50 may be located on the light-emitting layer 40. The electron transport layer 50 may be deposited on the light-emitting layer 40 according to a method arbitrarily selected from various known methods, such as a vacuum deposition method, a spin coating method, a spray method, a dip coating method, a bar coating method, a nozzle printing method, a slot-die coating method, a gravure printing method, a casting method, or a Langmuir-Blodgett (LB) film method. In this case, the conditions for the above deposition and coating conditions may vary depending on the target compound, the structure and thermal properties of the target layer, and the like.

Known electron transport materials can be used as the above electron transport layer 50, for example, 1,3,5-Tris(1-phenyl-1H-benzimidazol-2-yl)benzene (TPBi), 1,3,5-tri[(3-Pyridyl)-phen-3-yl]benzene (TmPyPB), Tris (2,4,6-trimethyl-3-(pyridin-3-yl)phenyl)borane (3TPYMB), Tris (8-hydroxy-quinolinato)aluminum (Alq₃), 3-(4-Biphenyl)-4-phenyl-5-tert-butylphenyl-1,2,4-triazole (TAZ), 4,7-Diphenyl-1,10-phenanthroline (Bphen), 2,9-Dimethyl-4,7-diphenyl-1,10-phenanthroline (BCP (Bathocuproine)), Bis(10-hydroxybenzo1h1quinolinato) beryllium (BeBq₂-) 1,3,5-tri(p-Pyrid-3-yl-phenyl)benzene (TpPyPB) or Bis(2-methyl-8-quinolinolate)-4-(phenylphenolato)aluminum (BAlq) can also be used.

The thickness of the electron transport layer 50 may be from about 10 nm to 100 nm. More specifically, it may be from 20 nm to 50 nm. When the thickness of the electron transport layer 50 satisfies the range as described above, excellent electron transport characteristics can be obtained without increasing the drive voltage.

On top of the above electron transport layer, an electron-injection layer 60 may be formed. The electron-injection layer 60 forming material may be LiF, NaCl, NaF, CsF, Li₂O, BaO, BaF₂, Cs₂CO₃ or Liq (lithium quinolate), which are electron injection materials of the disclosure.

The thickness of the electron-injection layer 60 may be from about 0.1 nm to 10 nm. More specifically, it may be from 0.5 nm to 5 nm. When the thickness of the above electron-injection layer 60 satisfies the above range, a satisfactory degree of electron injection characteristics can be obtained without substantially increasing the drive voltage.

Next, a second electrode may be located on the light-emitting layer 40 or the electron transport layer 50 or the electron-injection layer 60. For example, if the first electrode is an anode 20, the second electrode may be a cathode 70.

In this case, the above second electrode may comprise at least one selected from the group consisting of a metal having a relatively low work function, a conductive polymer, a metallic carbon nanotube, a graphene, a reduced graphene oxide, a metal nanowire, a carbon nanodot, a metal nanodot, and a conductive oxide, or a combination thereof. For example, the second electrode may include lithium (Li), magnesium (Mg), aluminum (Al), aluminum-lithium (Al—Li), calcium (Ca), magnesium-indium (Mg—In), magnesium-silver (Mg—Ag), and the like. ITO or IZO can also be used to obtain an all-emitting device.

The second electrode may also be formed using a vacuum deposition method.

Hereinafter, the present inventive concept will be described in detail by way of embodiments and experimental examples. However, the following embodiments and experimental examples are only illustrative of the present inventive concept, and the contents of the present inventive concept are not limited by the following embodiments and experimental examples.

### EXAMPLE 1

### Preparation of Perovskite Film With In Situ Core/Shell Nanocrystal Structure

Polycrystalline perovskite precursor solutions were prepared by dissolving organic and inorganic hybrid perovskites in polar solvents. Dimethylsulfoxide was used as the polar solvent and (FA_{0.7}GA_{0.2}MA_{0.1})_{0.87}Cs_{0.13}PbBr₃ was used as the organic-inorganic hybrid perovskite. The (FA_{0.7}GA_{0.2}MA_{0.1})_{0.87}Cs_{0.13}PbBr₃ was used with a ratio of (FABr+GABr+MABr+CsBr) to PbBr₂ of 1.15:1 and a concentration of (FA_{0.7}GA_{0.2}MA_{0.1})_{0.87}Cs_{0.13}PbBr₃ of 1.2 M in the total precursor solution. Ligand molecules were also added to the polycrystalline perovskite precursor solution at a concentration of (FA_{0.7}GA_{0.2}MA_{0.1})_{0.87}Cs_{0.13}PbBr₃ relative to 10 mol. %.

Ligand solutions were also prepared by dissolving the ligand molecule in a polar solvent. Tetrahydrofuran was used as the polar solvent and benzylphosphonic acid was used as the ligand molecule. Benzylphosphonic acid was prepared and used at a concentration of 17 mM in solution.

After the above polycrystalline perovskite precursor solution was applied to the glass substrate, the perovskite film was prepared by spin-coating while rotating the glass substrate at a speed of 6000 rpm.

The ligand solution was then applied to the perovskite film and a reaction time of 30 s was provided before spin-coating was performed by rotating the substrate at a speed of 6000 rpm to remove excess polar solvent and ligand.

The prepared thin films were annealed at 70° C. for 10 min.

### EXAMPLES 2-18

Instead of benzylphosphonic acid as the ligand molecule, phenylphosphonic acid, 2-phenylethylphosphonic acid, vinylphosphonic acid, and propadienylphosphonic acid, methylphosphonic acid, ethylphosphonic acid, propylphosphonic acid, isopropylphosphonic acid, butylphosphonic acid, and pentylphosphonic acid, n-hexylphosphonic acid, n-octylphosphonic acid, n-decylphosphonic, n-dodecylphosphonic, n-tetradecylphosphonic, and n=tetradecylphosphonic, n-hexadecylphosphonic acid, and n-octadecylphosphonic acid were used as ligand molecules, and perovskite films were prepared in the same manner as in Example 1.

### EXAMPLES 19-31

Instead of benzylphosphonic acid as the ligand molecule, phenylamine, benzylamine, phenethylamine, (N,N-diisopropylethylamine (N,N-diisopropylethylethylamine), ethylenediamine, hexamethylenediamine, methylamine, hexyl amine, oleylamine, N,N,N,N,N-tetramethylenediamine, triethylamine, diethanolamine, and 2,2-(ethylenedioxyl)bis-(ethylamine) were used as ligand molecules to prepare perovskite films in the same manner as in Example 1, except that 2,2-(ethylenedioxyl)bis-(ethylamine) was used as a ligand molecule.

### EXAMPLES 32-48

Instead of benzylphosphonic acid as the ligand molecule, 4,4′-Azobis(4-cyanovaleric acid), Acetic acid, 5-Aminosalicylic acid, Acrylic acid, L-Aspentic acid, 6-Bromohexanoic acid, Bromoacetic acid, Dichloro acetic acid, Ethylenediaminetetraacetic acid, Isobutyric acid, Itaconic acid, Maleic acid, r-Maleimidobutyric acid, L-Malic acid, 4-Nitrobenzoic acid, 1-Pyrenecarboxylic acid, or oleic acid were used as ligand molecules, and perovskite films were prepared in the same manner as in Example 1.

### EXAMPLES 49-58

Instead of benzylphosphonic acid as the ligand molecule, 4,4′-Azobis(4-cyanovaleric acid) (4,4′-Azobis(4-cyanovaleric acid)), Acetic acid, 5-Aminosalicylic acid, Acrylic acid, L-Aspentic acid, 6-Bromohexanoic acid, Bromoacetic acid, Dichloro acetic acid, Ethylenediaminetetraacetic acid, Isobutyric acid, Itaconic acid, Maleic acid, r-Maleimidobutyric acid, L-Malic acid, 4-Nitrobenzoic acid, 1-Pyrenecarboxylic acid, or oleic acid, 2-fluorophenylbornic acid, 3,5-diformyl-2-fluorophenylboronic acid, 3-chloro-4-fluorophenylboronic acid, 4-cyano-3-fluprpbenzoic acid, and L-Fmoc-3-fluorophenylalanine, L-Fmoc-4-fluorophenylalanine, Methyl 6-fluorochromone-2-carboxylic acid, 4-fluorobenzoic acid, 2-fluorobenzoic acid, and 2-fluoro benzylamine, 2-fluorocinnamic acid, 2-fluorophenyl isothiocyanate, and 4-fluorobenzenesulfonic acid, 4-flurobenzylamine, 4-fluorophenyl isothiocyanate, 4-fluorophenylacetic acid, Fluorocinnamic acid, (3-Fluoro-4-methylphenyl)acetic acid, (3-Fluoro-4-methylphenyl)acetic acid, (3-fluoro-5-isopropoxyphenyl)boronic acid ((3-fluoro-5-isopropoxyphenyl)boronic acid), (3-fluoro-5-methoxycarbonylphenyl)boronic acid ((3-fluoro-5-methoxycarbonylphenyl)b oronic acid), (3-fluoro-5-methylphenyl)boronic acid ((3-fluoro-5-methylphenyl)boronic acid), (4-fluoro-2-methoxyphenypoxoacetic acid ((4-fluoro-2-methoxyphenypoxoacetic acid), (4-fluoro-3-methoxyphenyl)acetic acid, and (4-fluoro-3-methoxyphenyl)boronic acid were used as ligand molecules to prepare perovskite films in the same manner as in Example 1, except that (4-fluoro-3-methoxyphenyl)acetic acid was used as a ligand molecule.

### EXAMPLES 59-61

Instead of benzylphosphonic acid as the ligand molecule, trifluoroiodomethane, pentafluoroethyl iodide, perfluorooctyl bromide (perfluorooctyl bromide, perflubron), dichlorodifluoromethane, trifluoroacetic acid, heptafluorobutryric acid, and pentafluorobenzoic acid, perfluorooctanoic acid, perfluorononanoic acid, triflic acid, perfluorobuanesulfonic acid, and perfluorobutane sulfonamide, perfluorooctanesulfonic acid were used as ligand molecules, and perovskite films were prepared in the same manner as in Example 1.

### Comparative Example 1

### Preparation of Perovskite Film (Three-Dimensional (3D) Structure)

Perovskite films were prepared in the same way as in Example 1, except that the application and coating process of the ligand solution was omitted, and the ligand was not added to the polycrystalline perovskite precursor solution.

### Comparative Example 2

### Preparation of Perovskite Film (In Situ Particle Structure)

Perovskite films were prepared in the same way as in Example 1, except that the application and coating process of the ligand solution was omitted.

### Experimental Example 1

### Size Variation of Perovskite Crystals by In Situ Nanocrystal Formation Process

In order to investigate the morphological changes of the perovskite crystals due to the in situ nanocrystal formation process in the preparation of the perovskite films according to the present inventive concept, high-resolution transmission electron microscopy images of the perovskite films prepared in Example 1 and Comparative Examples 1-2 were analyzed, and the results are shown in FIG. 5-11.

As shown in FIG. 5, the grains of the polycrystalline film with a reaction time of 1 second with the ligand solution, where little reaction has occurred, have a large crystal size on the order of 200 nm. On the other hand, as the reaction time of 10, 20, and 30 s is provided, the crystal size gradually decreases, and the enlarged boundaries are well aligned. This suggests that the reaction with the ligand solution causes the crystals to split around defects on the surface and inside, decrease in size, and become surrounded by ligand molecules to form a core/shell nanocrystal structure.

### Experimental Example 2

### Changes in Surface Structure of Perovskite Film by In Situ Nanocrystal Formation Process

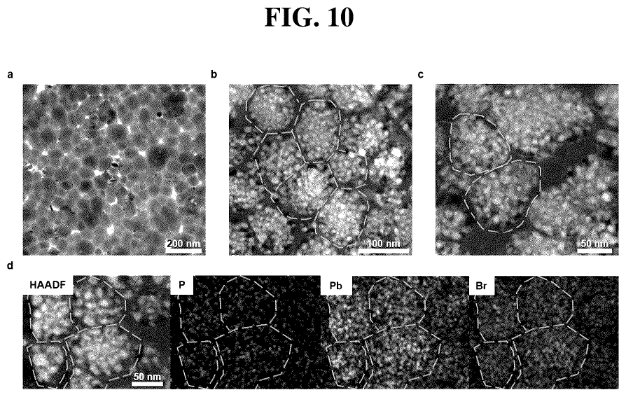

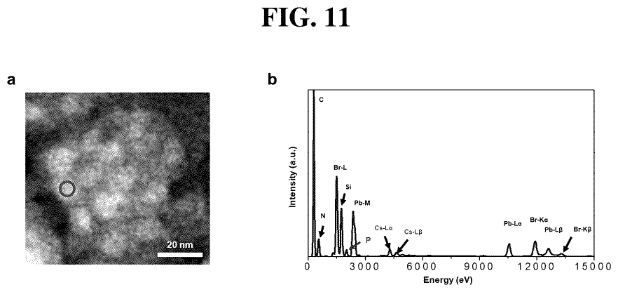

In the preparation of the perovskite film according to the present inventive concept, high-resolution electron energy loss spectroscopy (EELS) (FIG. 8-9) and energy dispersive spectroscopy (EDS) (FIG. 10-11) on the surface of the perovskite film prepared in Example 1 were analyzed to investigate the changes in the surface structure of the perovskite crystals due to the in situ nanocrystal formation process.

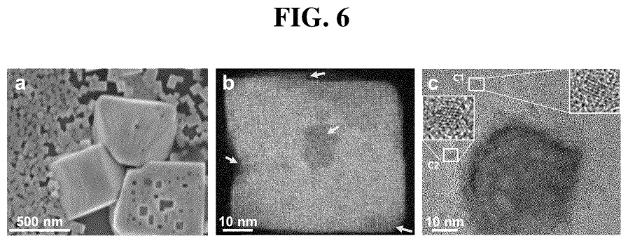

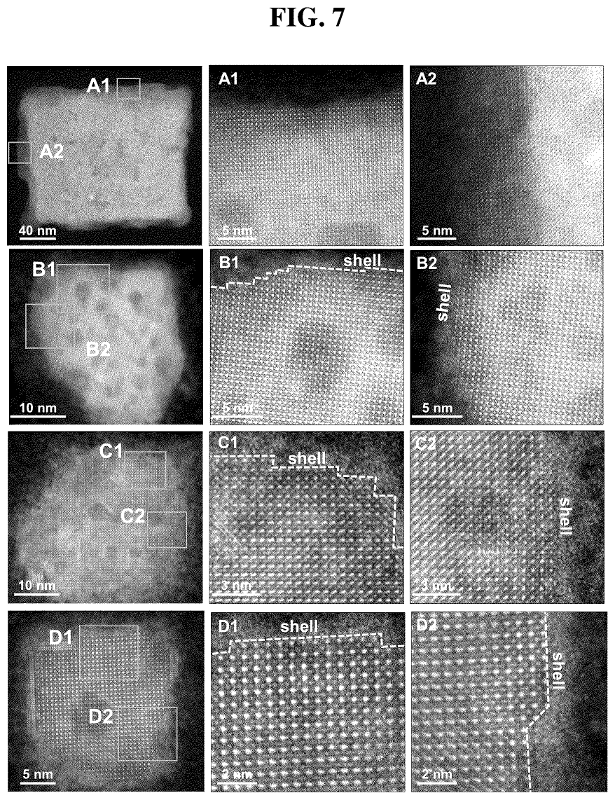

As shown in FIG. 6, the high-resolution electron energy loss spectrum clearly shows the perovskite crystal lattice structure, with Pb and Br elements originating from perovskite in the core region (A) and P elements originating from benzylphosphonic acid in the peripheral shell region (B) surrounding it. Furthermore, as shown in FIG. 7-8, the periphery of the perovskite nanocrystal is surrounded by P elements originating from benzylphosphonic acid. This indicates that the provided ligand molecules form a core/shell conformation with the shell surrounding the inner perovskite core.

### Experimental Example 3

### Changes in Chemical Structure of Perovskite Film by In Situ Nanocrystal Formation Process

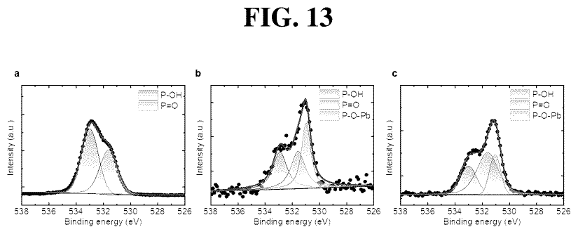

In order to investigate the chemical bonding characteristics of the ligand molecules and the perovskite in the preparation of the perovskite films according to the present inventive concept following the ligand solution treatment, the results of X-ray photoelectron spectroscopy (XPS) measurements of the oxygen element present in the benzylphosphonic acid molecules for the perovskite films prepared in Example 1 and Comparative Example 2 are shown in FIG. 13.

First, it can be seen that when the benzylphosphonic acid molecule alone is present, the P—OH bond (533 eV) and P═O bond (532 eV) are present in a 2:1 ratio. However, when benzylphosphonic acid is added to the polycrystalline perovskite precursor solution, either in the case of the in situ particle structure (Example 2) or in the case of the in situ core/shell nanocrystal structure (Example 1) after ligand solution treatment, an additional bonding peak is seen to form around 531 eV. This corresponds to the covalent bond of P—O—Pb with Pb atoms on the perovskite surface, which is a new bonding state, confirming that the benzylphosphonic acid ligand binds to the surface in the form of a covalent bond to form a stable core/shell structure. The ligands used in colloidal nanocrystal particles, which are synthesized by dissolving surfactants and injecting perovskite precursors to be used as ligands in the colloidal phase, are not chemically attached by covalent bonds, but maintain a state of dynamic binding, which is repeatedly attached and detached. However, in the present inventive concept, the ligand is not a ligand with the dynamic binding of conventional colloidal nanocrystal particles, but a shell material that maintains a covalent binding state.

### Experimental Example 4

### Changes in Charge Transport Capability Properties of Perovskite Film Due to Formation of In Situ Core/Shell Nanocrystal Structure

In order to investigate the charge transport capability characteristics of the films of perovskite due to the formation of the in situ core/shell nanocrystal structure in the preparation of the perovskite films according to the present inventive concept, single-carrier devices were fabricated and characterized for the perovskite films prepared in Example 1 and Comparative Example 2. The trap density and charge transport capability were measured by characterizing the ohmic region at low voltages, where only the movement of thermalized charge is observed, the trap-filling-limit region, where defects begin to fill, and the space charge limit current (SCLC) region at high voltages, where the behavior of the injected charge is mainly observed after all the defects are filled.

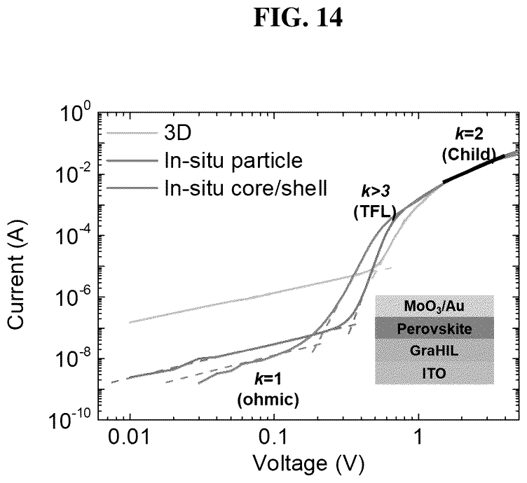

As shown in FIG. 14, the defect density of the perovskite film is significantly reduced in the in situ core/shell nanocrystal structure (1.37×10¹⁶ cm⁻³) compared to the conventional three-dimensional structure (3.50×10¹⁶ cm⁻³) and the in situ particle structure (2.36×10¹⁶ cm⁻³). On the other hand, the charge mobility is not significantly different between the conventional three-dimensional structure (3.26×10⁻² cm² V⁻¹ s⁻¹) and the in situ particle structure (3.08×10⁻² cm² V⁻¹ s^{31 1}) and the in situ core/shell nanocrystal structure (2.99×10⁻² cm² V⁻¹ s⁻¹). This suggests that the ligands used in the formation of the in situ core/shell structure reduce the defect density without significantly degrading the charge transport properties.

As such, the perovskite film having an in situ core/shell nanocrystal structure according to the present inventive concept can be usefully employed as a light-emitting layer of a light emitting device because it maintains excellent charge transport properties while lowering the defect density of conventional polycrystalline perovskite films.

### Experimental Example 5

### Changes in Photoluminescence Properties of Perovskite Film Due to Formation of In Situ Core/Shell Nanocrystal Structure

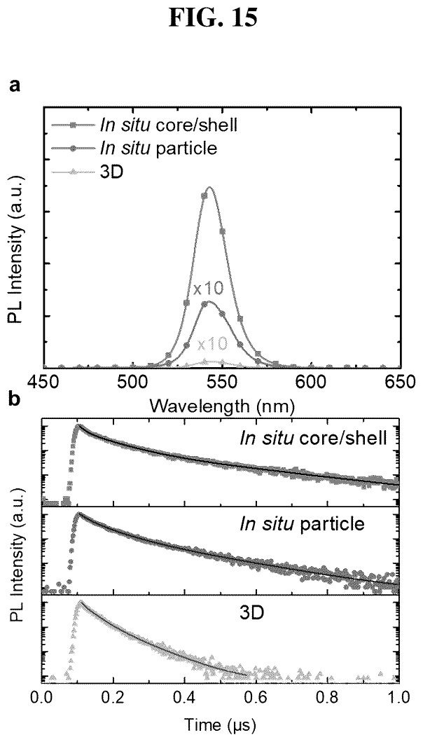

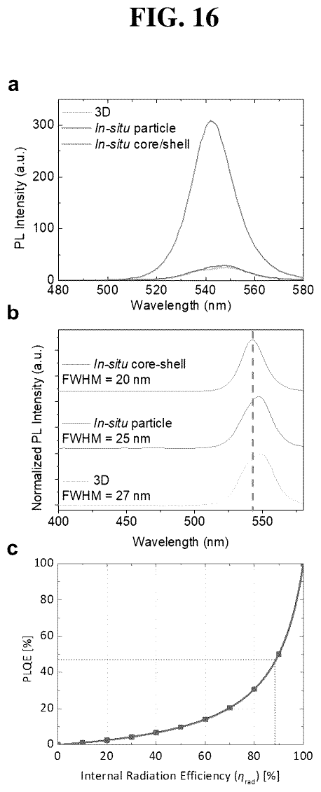

In order to investigate the photoluminescence properties of the perovskite films according to the in situ core/shell nanocrystal formation in the preparation of the perovskite films according to the present inventive concept, the photoluminescence intensity, charge lifetime, and photoluminescence quantum efficiency were measured for the perovskite films prepared in Example 1 and Comparative Examples 1-2, and the results are shown in FIG. 15-16.

As shown in FIG. 15-16, it can be seen that compared to the conventional 3D crystal structure of Comparative Example 1 and the perovskite film with the in situ particle structure of Comparative Example 2, the perovskite film with the in situ core/shell nanocrystal structure exhibits much stronger photoluminescence intensity and longer photoluminescence lifetime. It can also be seen that the photoluminescence quantum efficiency was only about 30% for the three-dimensional structure and the in situ particle structure, while the in situ core/shell nanocrystal structure exhibited a high photoluminescence quantum efficiency of about 90%.

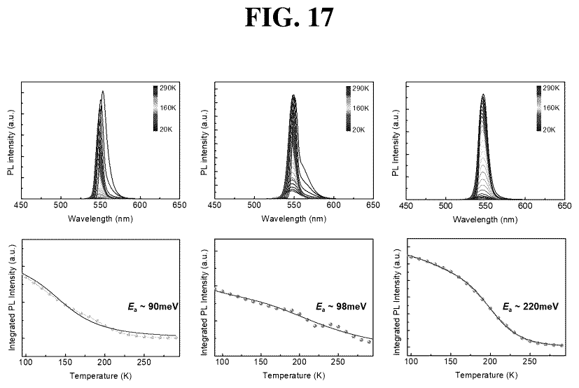

Furthermore, to compare the strength of charge confinement in the perovskite films due to the in situ core/shell nanocrystal formation, the temperature-dependent photoluminescence intensity was measured for the perovskite films prepared in Example 1 and Comparative Examples 1-2, and the results are shown in FIG. 17.

As shown in FIG. 17, the exciton binding energy, which is the energy barrier for the decrease in photoluminescence properties with increasing temperature, was around 90-100 meV for the conventional three-dimensional structure and the in situ particle structure, while the in situ core/shell nanocrystal structure showed a very high exciton binding energy of 220 meV. This can be attributed to the enhanced charge confinement effect through nanocrystal formation.

As such, the perovskite film having an in situ core/shell nanocrystal structure according to the present inventive concept exhibits significantly increased luminescence properties and charge lifetime characteristics and excellent charge confinement effect compared to conventional polycrystalline perovskite films, and thus can be usefully employed as a light-emitting layer of a light emitting device.

### Manufacturing Example

### Light Emitting Diode Manufacturing

First, an FTO substrate (a glass substrate coated with an FTO anode) was prepared, and then a conductive material, PEDOT:PSS (AI4083 from Heraeus), was spin-coated on the FTO anode and heat-treated at 120° C. for 30 minutes to form a 75 nm thick hole-injection layer.

Next, the polycrystalline perovskite precursor solution prepared in Example 1 was applied to the above hole-injection layer and spin-coated while rotating at a speed of 6000 rpm. Then, the ligand solution prepared in Example 1 was applied to the perovskite film, and after 30 s, it was spin-coated while rotating at a speed of 6000 rpm, and the prepared thin film was heat treated at 70° C. for 10 minutes to form a perovskite light-emitting layer having an in situ core/shell nanocrystal structure.

Then, a 45 nm thick 2-[4-(9,10-Di-naphthalen-2-yl-anthracen-2-yl)-phenyl]-1-phenyl-1H-benzoimidazole (ZADN) is deposited on the above perovskite light-emitting layer in a high vacuum of 1×10⁻⁷ Torr or less to form an electron transport layer, A 1 nm thick LiF layer was deposited on top to form the electron-injection layer, and a 100 nm thick aluminum layer was deposited on top to form the cathode to produce a perovskite light emitting diode.

### Comparative Example 3

Perovskite light-emitting diodes were fabricated by conventional methods without the addition of benzylphosphonic acid to the polycrystalline perovskite precursor solution and coating with a ligand solution.

### Comparative Example 4

Perovskite light-emitting diodes were fabricated by conventional methods without ligand solution coating on polycrystalline perovskite films.

### Experimental Example 6

### Measuring the Current Efficiency of a Light-Emitting Diode

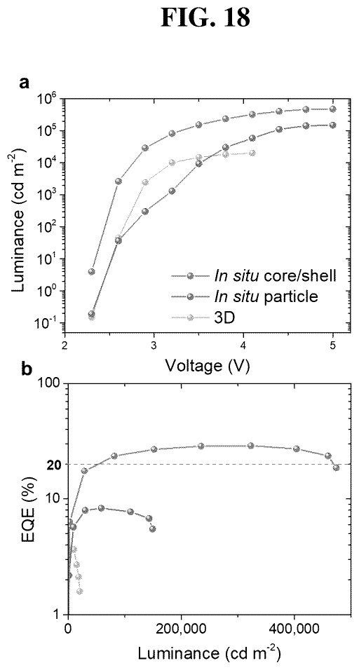

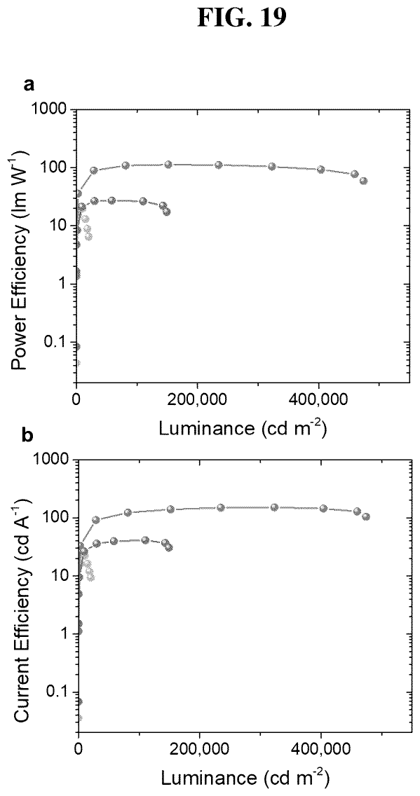

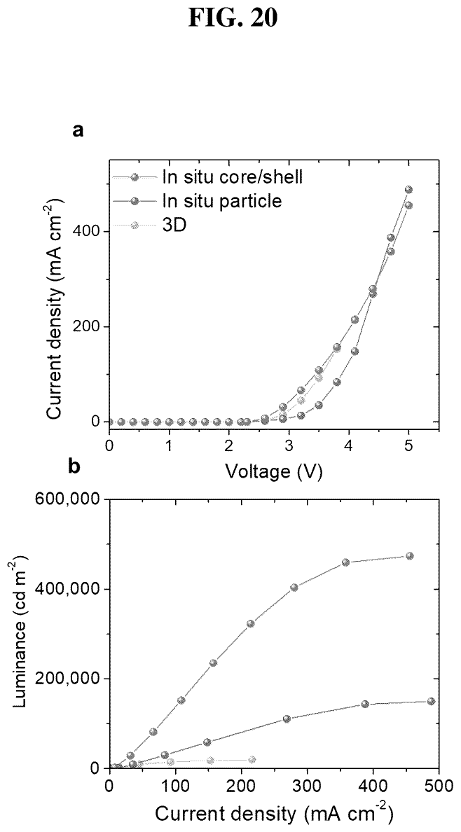

In the perovskite light-emitting diode according to the present inventive concept, the current efficiency was measured for the perovskite light-emitting diode manufactured in the manufacturing example and the comparison example 3-4, and the results are shown in FIG. 18-20.

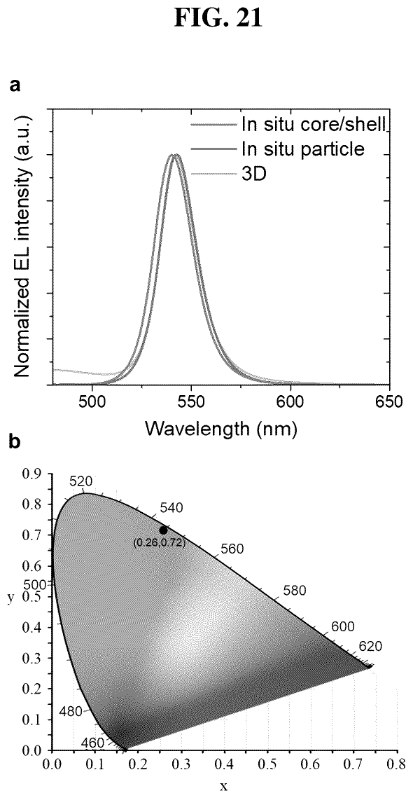

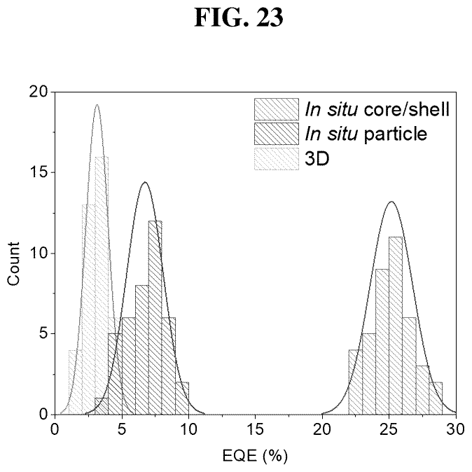

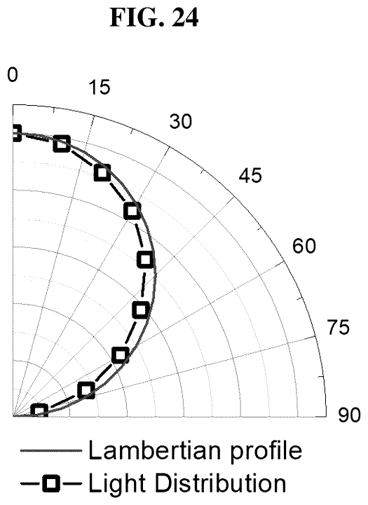

As shown in FIG. 18, compared to the conventional perovskite light emitting diodes of Comparative Examples 3-4, the current efficiency and luminance of the perovskite light emitting diodes comprising a perovskite light-emitting layer having an in situ core/shell nanocrystal structure according to the present inventive concept were found to be significantly improved. In particular, a maximum external quantum efficiency of 28.9% (average of 25.2% for a total of 40 samples) was obtained, which is the maximum efficiency that can be obtained theoretically with the present device structure, and a maximum luminance of 473,990 cd m⁻² was obtained, which is much higher than any of the prior reports. (FIG. 21-24)

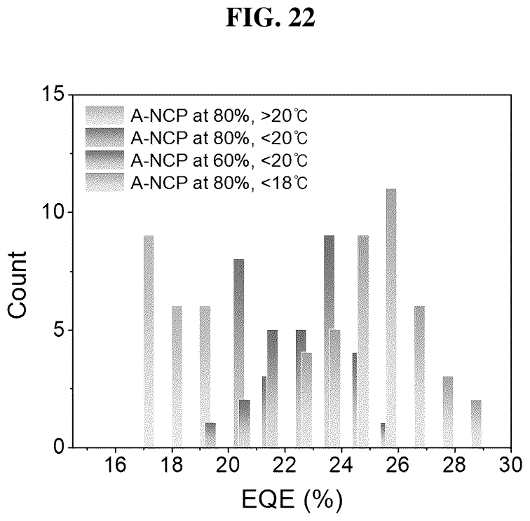

Furthermore, as shown in FIG. 22, these highly efficient devices are very sensitive to the temperature of the thin film application and the timing of the nanocrystal pinning process. It is important to introduce a sufficiently low temperature for nanocrystal formation and a timing of immobilization that is not too late to prevent the perovskite precursor thin film from becoming too large in size.

This is attributed to the fact that the perovskite light-emitting layer with the in situ core/shell nanocrystal structure according to the present inventive concept has excellent charge confinement and charge transport properties at the same time, resulting in ideal charge injection and light emission.

The device efficiency as a function of benzylphosphonic acid solution concentration and reaction time for the above in situ core-shell structure is tabulated in detail and shown in Table 3 and Table 4, respectively.

In addition, light-emitting diodes with the same conditions were prepared by partially replacing benzylphosphonic acid with methylphosphonic acid, which has a shorter ligand length, and the efficiency was measured. In this case, the charge injection into the perovskite crystal was enhanced by the reduction in ligand length, resulting in a significant improvement in drive efficiency, luminance, and power efficiency at lower voltages. The device efficiency as a function of the ratio of benzylphosphonic acid (BPA)/methylphosphonic acid (MPA) ligands in the above in situ core-shell structure is further tabulated and shown in Table 5.

TABLE 3

| BPA Solution | Maximum | Maximum current | Maximum external |
|---|---|---|---|
| Concentration | luminance | efficiency | quantum efficiency |
| [mM] | [cd m⁻²] | [cd A⁻¹] | [%]. |
| 0 | 123825 | 45 | 8.6 |
| 5 | 165290 | 56 | 10.7 |
| 10 | 201919 | 65 | 12.4 |
| 11 | 238600 | 84 | 16.1 |
| 12 | 263498 | 99 | 18.9 |
| 13 | 310437 | 117 | 22.4 |
| 14 | 342342 | 132 | 25.3 |
| 15 | 417331 | 145 | 27.8 |
| 16 | 394362 | 148 | 28.3 |
| 17 | 473990 | 151 | 28.9 |
| 18 | 448680 | 146 | 27.9 |
| 19 | 341495 | 133 | 25.5 |
| 20 | 401405 | 129 | 24.7 |
| 25 | 351921 | 120 | 23.0 |
| 30 | 322575 | 113 | 21.6 |
| 40 | 256645 | 101 | 19.3 |
| 50 | 232549 | 85 | 16.3 |

TABLE 4

| BPA solution | Maximum | Maximum current | Maximum external |
|---|---|---|---|
| reaction time | luminance | efficiency | quantum efficiency |
| [s] | [cd m⁻²] | [cd A⁻¹] | [%]. |
| 0 | 128014 | 50.9 | 9.7 |
| 5 | 147052 | 57.2 | 10.9 |
| 10 | 161347 | 63.3 | 12.1 |
| 15 | 217119 | 76.4 | 14.6 |
| 20 | 231227 | 83.7 | 16.0 |
| 21 | 257131 | 90.9 | 17.4 |
| 22 | 268961 | 102.8 | 19.7 |
| 23 | 271672 | 98.9 | 18.9 |
| 24 | 299238 | 109.1 | 20.9 |
| 25 | 297355 | 108.8 | 20.8 |
| 26 | 321812 | 122.0 | 23.3 |
| 27 | 367902 | 132.9 | 25.4 |
| 28 | 333493 | 131.5 | 25.2 |
| 29 | 408077 | 137.0 | 26.2 |
| 30 | 473990 | 149.1 | 28.9 |
| 31 | 425075 | 143.7 | 27.5 |
| 32 | 363055 | 139.9 | 26.8 |
| 33 | 382380 | 137.9 | 26.4 |
| 34 | 395773 | 144.8 | 27.7 |
| 35 | 348117 | 138.0 | 26.4 |
| 36 | 366677 | 133.9 | 25.6 |
| 37 | 370903 | 127.0 | 24.3 |
| 38 | 370082 | 130.6 | 25.0 |
| 39 | 316287 | 121.7 | 23.3 |
| 40 | 343800 | 124.2 | 23.8 |
| 45 | 296824 | 116.4 | 22.3 |
| 50 | 318340 | 105.0 | 20.1 |
| 55 | 256486 | 100.4 | 19.2 |
| 60 | 275819 | 89.5 | 17.1 |
| 70 | 233986 | 78.2 | 15.0 |
| 80 | 200098 | 66.6 | 12.7 |
| 90 | 180536 | 61.3 | 11.7 |

TABLE 5

| Molar ratio of BPA | | | |
|---|---|---|---|
| to MPA in ligand | Maximum | Maximum power | Maximum external |
| solution [%] | luminance | efficiency | quantum efficiency |
| (at 17 mM) | [cd m⁻²] | [lm W⁻¹] | [%]. |
| 0 | 473990 | 112.6 | 28.9 |
| 10 | 454027 | 119.7 | 30.2 |
| 20 | 478581 | 121.5 | 30.1 |
| 25 | 429768 | 119.2 | 29.3 |
| 26 | 430119 | 117.9 | 28.9 |
| 27 | 456194 | 122.1 | 29.9 |
| 28 | 472084 | 121.6 | 29.7 |
| 29 | 478161 | 124.1 | 30.3 |
| 30 | 495512 | 125.2 | 30.5 |
| 31 | 439293 | 117.7 | 28.7 |
| 32 | 420019 | 116.2 | 28.3 |
| 33 | 416985 | 116.0 | 28.4 |
| 34 | 451495 | 115.5 | 28.3 |
| 35 | 446753 | 114.3 | 28.4 |
| 40 | 388650 | 102.0 | 26.2 |
| 50 | 391269 | 100.4 | 25.9 |
| 60 | 345401 | 90.9 | 24.3 |
| 80 | 386297 | 104.7 | 28.6 |
| 100 | 311672 | 79.2 | 21.7 |

### Example 7

### Measuring the Operating Life of a Light-Emitting Diode

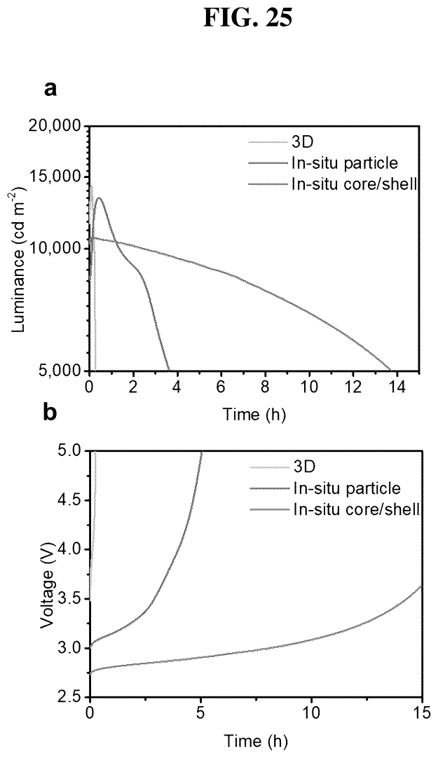

For the perovskite light emitting diode according to the present inventive concept, the driving life was measured at an initial luminance of 10,000 cd m⁻² for the perovskite light emitting diode manufactured in the manufacturing example and Comparative Examples 3-4, and the results are shown in FIG. 25.

As shown in FIG. 25, the driving lifetime of the conventional perovskite light-emitting diodes of Comparative Examples 3-4 cannot exceed 0.2 hours and 4 hours, respectively, but the perovskite light-emitting diode comprising a perovskite light-emitting layer having an in situ core/shell nanocrystal structure according to the present inventive concept shows a significantly improved lifetime by emitting for more than 13 hours at an initial luminance as high as 10,000 cd m⁻². This is attributed to the stabilization of defects on the surface and inside the perovskite crystal by the shell.

Furthermore, in the perovskite light emitting diode according to the present inventive concept, the operational lifetime was measured under various initial luminance conditions for the perovskite light emitting diode prepared in the manufacturing example, and the results are shown in FIG. 18.

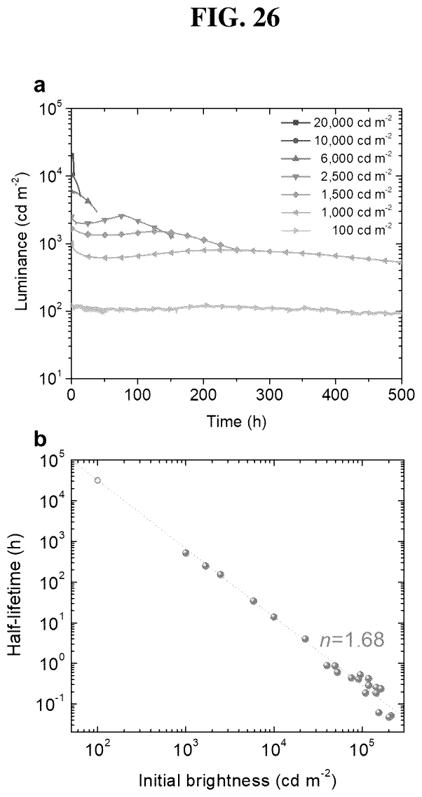

As shown in FIG. 26, the perovskite light-emitting diode fabricated in the embodiment was driven for over 500 hours at an initial luminance of 1,000 cd m⁻² and for over 500 hours at an initial luminance of 100 cd m⁻² with little device degradation. When calculating the lifetime according to the accelerated lifetime test formula (Lⁿ T=constant, L=initial luminance [cd m⁻²], T=lifetime [h], n=acceleration factor) utilized in the conventional organic light emitting diode field, it was found to have a long operating lifetime of about 30,108 hours at an initial luminance of 100 cd m⁻².

As such, a light-emitting device comprising a perovskite film having an in situ core/shell nanocrystal structure according to the present inventive concept as a light-emitting layer exhibits significantly improved current efficiency and operational lifetime compared to a conventional light-emitting device comprising a conventional perovskite film, and thus can be usefully used in place of a conventional light-emitting device.

Furthermore, the perovskite light-emitting diode with this in situ core/shell nanocrystal structure was applied to a large-area device with emission area of more than 100 mm², which is much larger than the conventional emission area of 5 mm². As a result, highly uniform large-area light emission, high driving luminance of more than 100,000 cd m⁻² and high external quantum efficiency of 22.4% were obtained.

The embodiments of the inventive concept disclosed herein and in the drawings are shown by way of illustration only and are not intended to limit the scope of the inventive concept. That other modifications based on the technical ideas of the present inventive concept may be practiced in addition to the embodiments disclosed herein will be apparent to one of ordinary skill in the technical field to which the present inventive concept belongs.

1. A perovskite material with an in situ core/shell nanocrystal structure comprising:
a core of halide perovskite nanocrystals; and
a self-assembled shell surrounding the core,
wherein the core comprises perovskite nanocrystals that includes a structure of ABX₃ (3D), A₄BX₆ (0D), AB₂X₅ (2D), A₂BX₄ (2D), A₂BX₆ (0D), A₂B⁺B³⁺X₆(3D), A₃B₂X₉ (2D) or Aₙ₋₁BₙX₃ₙ₊₁ (quasi-2D), where n is an integer between 2 and 6,
wherein the perovskite nanocrystal includes an in situ core/shell perovskite nanocrystal structure formed by in situ reaction of solid phase polycrystalline perovskite with a solution of organic ligand (Y).
wherein the organic ligand can bind to the surface of the perovskite nanocrystal and surrounds it to form a core/shell structure.

2. The perovskite material with an in situ core/shell nanocrystal structure of claim 1,
wherein the organic ligand comprises at least one species selected from the group consisting of phosphonic acid, carboxylic acid, sulfonic acid, alkyl halide, alkyl ammonium halide, alkyl amine, and alkali halide.

3. The perovskite material with an in situ core/shell nanocrystal structure of claim 5,
wherein A and A′ is an organoammonium ion, an organophosphonium ion, or an alkali metal ion,
B is a transition metal, an alkaline earth metal, a rare earth metal, Pb, Sn, Ge, Ga, In, Al, Sb, Bi, Po, or a combination thereof, and
X is Cl, Br, I, a cyanide ion, a cyanide sulfide ion, or a combination thereof.

4. The perovskite material with in situ core/shell nanocrystal structure of claim 1,
wherein the above perovskite nanocrystals have a size of 10 nm to 20 nm.

5. A method for manufacturing a perovskite film with an in situ core/shell nanocrystal structure, comprising:
preparing polycrystalline perovskite films ; and
performing a reaction, comprising applying a ligand solution to the polycrystalline perovskite film,
wherein the reaction includes the step (S100) of splitting crystals to form nanocrystals and preparing a core/shell nanocrystal structure surrounded by a ligand.

6. The perovskite film with an in situ core/shell nanocrystal structure of claim 5,
wherein organic ligand is selected from the group consisting of phosphonic acid, carboxylic acid, sulfonic acid, alkyl halide, alkyl ammonium halide, alkyl amine, and alkali halide.

7. A method for manufacturing the perovskite film in situ core/shell nanocrystal structure of claim 5,
wherein the ligand solution may comprises one or more solvents selected from the group consisting of water, alcohol (methanol, ethanol, n-propanol, 2-propanol, n-butanol, etc.), formic acid, nitromethane, acetic acid, ethylene glycol, glycerol, normal methyl pyrrolidone (NMP, n-Methyl-2-Pyrrolidone), N-dimethyl acetamide (N.N-dimethylacetamide), dimethylformamide (DMF), dimethyl sulf oxide (DMSO), tetrahydrofuran (THF), and ethyl acetate (EtOAc), acetone (acetone), and acetonitrile (MeCN).

8. A method for manufacturing the perovskite film in situ core/shell nanocrystal structure of claim 5,
wherein the concentration of the ligand molecule in the ligand solution applied to the perovskite polycrystalline thin film is 10 mM to 20 mM.

9. A method for manufacturing the perovskite film with an in situ core/shell nanocrystal structure of claim 9,
wherein the reaction time with the polycrystalline thin film after applying the ligand solution to the perovskite polycrystalline thin film and before coating is in the range of 30 seconds to 50 seconds.

10. A method for manufacturing the perovskite film of claim 9,
wherein the method further comprises the step of coating the ligand solution by a method selected from the group consisting of spin coating, bar coating, nozzle printing, spray coating, slot die coating, gravure printing, inkjet printing, screen printing, electrohydrodynamic jet printing, and electrospray.

11. The perovskite light emitting device of claim 1, comprising:
a substrate;
a first electrode located on the substrate;
a light-emitting layer located on the first electrode; and
a second electrode positioned on the light-emitting layer,
wherein the light-emitting layer comprises a perovskite film with an in situ core/shell nanocrystal structure.

12. The perovskite light emitting device of claim 11,
wherein the light-emitting layer has a thickness of from 10 nm to 10 μm.

13. The perovskite light emitting device of claim 11,
wherein each of the first electrode and the second electrode independently comprises at least one species selected from the group consisting of a metal, a conductive polymer, a metallic carbon nanotube, a graphene, a reduced graphene oxide, a metal nanowire, a carbon nanodot, a metal nanodot, and a conductive oxide.

14. The perovskite light emitting device of claim 11,
wherein the perovskite light-emitting device is selected from the group consisting of a light-emitting diode, a light-emitting transistor, a laser, and a polarized light-emitting device.
